(19) United States
(12) Patent Application Publication
(10) Pub. No.: US 2025/0210409 A1
(43) Pub. Date: Jun. 26, 2025

(54) DEVICE WITH ELECTRICAL COMPONENT FORMED OVER A CAVITY AND METHOD THEREFOR

(71) Applicant: NXP USA, Inc., Austin, TX (US)

(72) Inventors: Philippe RENAUD, Chandler, AZ (US); Bruce McRae GREEN, Gilbert, AZ (US)

(21) Appl. No.: 18/393,186

(22) Filed: Dec. 21, 2023

(51) Int. Cl. H01L 21/762; H01L 23/66; H03H 9/54

(52) U.S. Cl. CPC H01L 21/7624; H01L 23/66; H03H 9/542; H10D 1/20; H01L 2223/6672

(57) ABSTRACT

A semiconductor device and method of manufacture is presented. A silicon-on-insulator (SOI) substrate includes a layer of gallium nitride on a first surface of the SOI substrate. A device is formed over the first surface of the substrate and a first conductive feature is formed over the first surface of the substrate and electrically coupling the first conductive feature to the device. A first cavity is formed in a second surface of the SOI substrate directly below the first conductive feature, wherein the first cavity includes first upper cavity surface defined by a surface of a layer of silicon dioxide in the SOI substrate.

### TECHNICAL FIELD

Embodiments of the subject matter described herein relate generally to devices for radio frequency (RF) applications and, more specifically, to devices incorporating components formed over a cavity in a device substrate.

### BACKGROUND

Gallium nitride (GaN) RF power transistors provide 2-3 times higher output impedance and power density than their silicon (Si) counterparts. GaN on Si technology is desired for lower cost, high performance RF applications. However, GaN on Si technology requires increasingly thin substrates (e.g., 50 microns or less) to effectively dissipate heat generated in GaN transistors. At the same time, applications demand integrated passive devices (IPDs) and higher levels of integration to lower assembly cost. Thinner substrates lower the quality factor (Q) of passive components (e.g., inductors, transmission lines) and further reduce characteristic impedance of transmission lines in IPDs. Lower Q passive components result in higher overall system losses. In addition, high impedance transmission lines are needed for many applications such as inductive components, bias networks, and distributed amplifiers, among others. However, thinner Si substrates drive the need to make transmission line traces narrower to realize a transmission line of desired impedance. The narrower traces limit the maximum realizable impedance for a GaN on Si process technology. In addition, electro-migration effects limit the use of these narrow, high impedance transmission lines. This electro-migration limit may limit the current-carrying capability of these transmission lines to between 2 and 10 milliamps per millimeter of conductor width, depending on the metal used and thickness of the line. Therefore, power efficient and high performance designs desire higher Q passive components such as inductors and higher impedance transmission lines for GaN on Si devices.

Some GaN devices are formed over Si substrate, where the Si substrate includes a layered silicon-insulator-silicon structure, which is commonly referred to as a silicon-on-insulator (SOI) structure. This SOI substrate configuration can improve device performance by reducing parasitic capacitances within the substrate. SOI substrate can realize additional benefits such as eliminating substrate leakage, reducing cross talk between circuit components, and ultimately increase the electrical performance of device formed over such substrates.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures.

FIG. 1 is a top view of a device in accordance with an embodiment.

FIG. 2 is a cross sectional view of the device of FIG. 1 along line 2-2, in accordance with an embodiment.

FIG. 3 is a cross sectional view of the device of FIG. 1 along line 3-3, in accordance with an embodiment.

FIG. 4 is a cross sectional view of an electronic assembly in accordance with an embodiment.

FIG. 5 is a flowchart of a method of fabricating the device of FIG. 1, according to an embodiment.

FIGS. 6-20 display simplified cross sectional views of a series of fabrication steps for forming the device of FIG. 1, according to an embodiment.

### DETAILED DESCRIPTION

The following detailed description is merely illustrative in nature and is not intended to limit the embodiments of the subject matter or the application and uses of such embodiments. As used herein, the words “exemplary” and “example” mean “serving as an example, instance, or illustration.” Any implementation described herein as exemplary or an example is not necessarily to be construed as preferred or advantageous over other implementations. Furthermore, there is no intention to be bound by any expressed or implied theory presented in the preceding technical field, background, or the following detailed description.

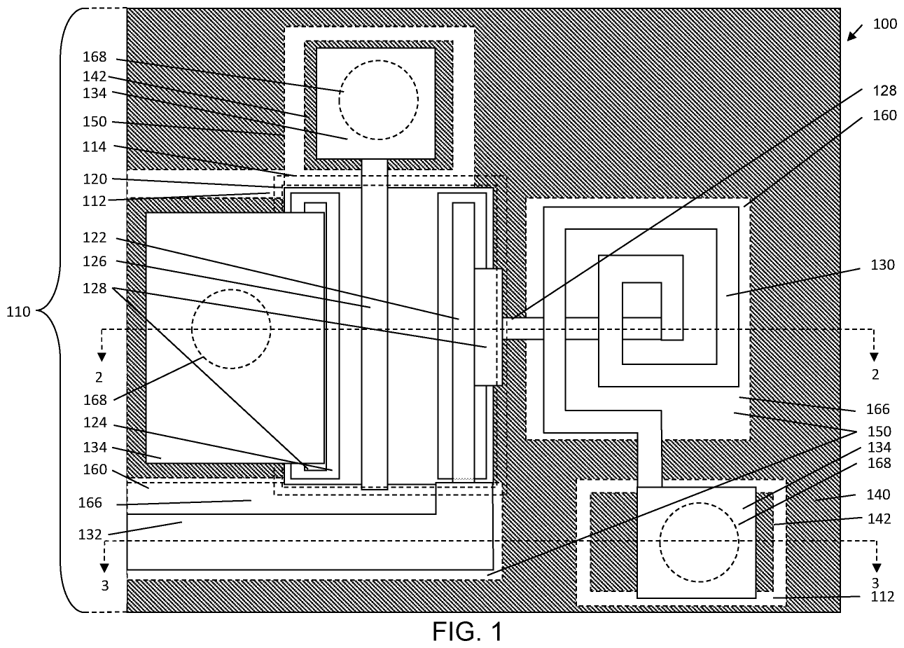

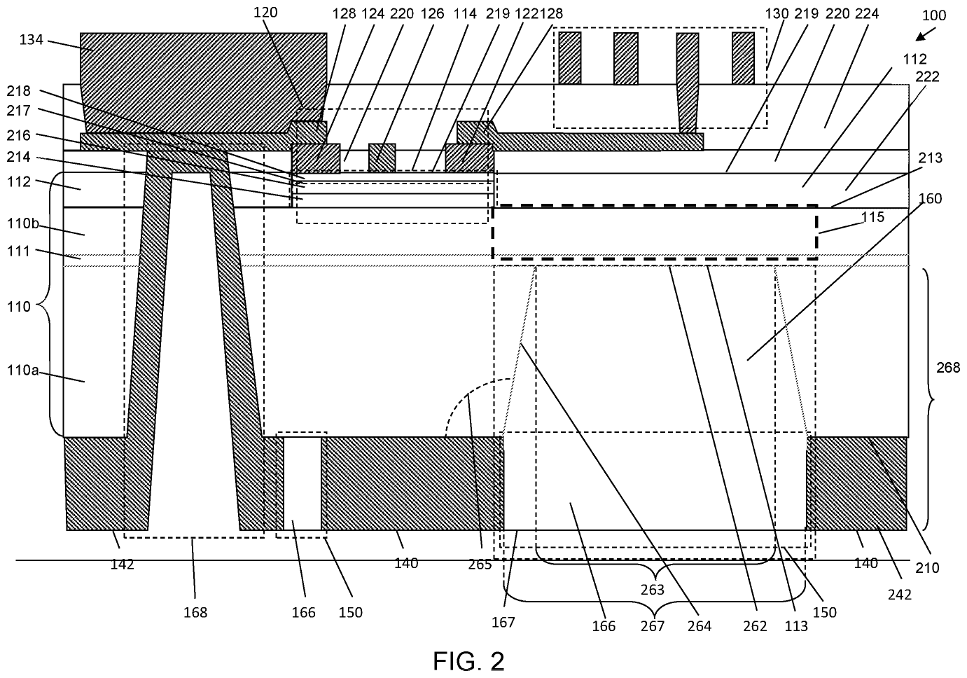

FIG. 1 is a top view of an exemplary device 100 in accordance with an embodiment. Device 100 includes a semiconductor substrate 110 configured as a silicon-on-insulator (SOI) substrate, one or more transistor(s) 120, one or more first conductive feature(s) (e.g. inductor 130, transmission line 132, and/or top interconnect structures 134), one or more second conductive feature(s) 140 (e.g. back metal 140 and/or backside contact 142), one or more first conductor-less region(s) 150 and one or more cavities 160 below one or more of the first conductor-less region(s) 150 and aligned with corresponding first conductive feature(s) 130, 132. As used herein, a “first conductive feature” refers to a conductive structure formed on or over the top substrate surface 219 of FIG. 2, and a “second conductive feature” refers to a conductive structure formed on or over the bottom substrate surface 210 of FIG. 2. In various embodiments, conductive feature 130 may include an inductor (as in the example of FIG. 1), or other passive components, such as a capacitors (or, at least, a plate of a capacitor), resistor, or combinations thereof.

For clarity of illustration, although they would be hidden in the top view, back metal 140 and backside contacts 142 are depicted in the top view of FIG. 1 as cross-hatched regions having boundaries defined with dashed lines. Similarly, cavities 160 and through wafer vias 168 also would be hidden in the top view, and thus the boundaries of cavities 160 and through wafer vias 168 also are indicated with dashed lines. Further, although device 100 is shown to include two cavities 160, other device embodiments may include more or fewer cavities, and/or the cavities may be located in different portions of the device than those depicted in FIGS. 1-4. It should be appreciated that the description of device 100 and arrangement and connection of its elements such as transistor 120, first and second conductive features 130, 132, 134, 140, and 142, conductor-less region(s) 150, cavities 160, and through wafer vias 168 are exemplary and are not intended to limit the scope of the inventive subject matter only to the illustrated embodiments.

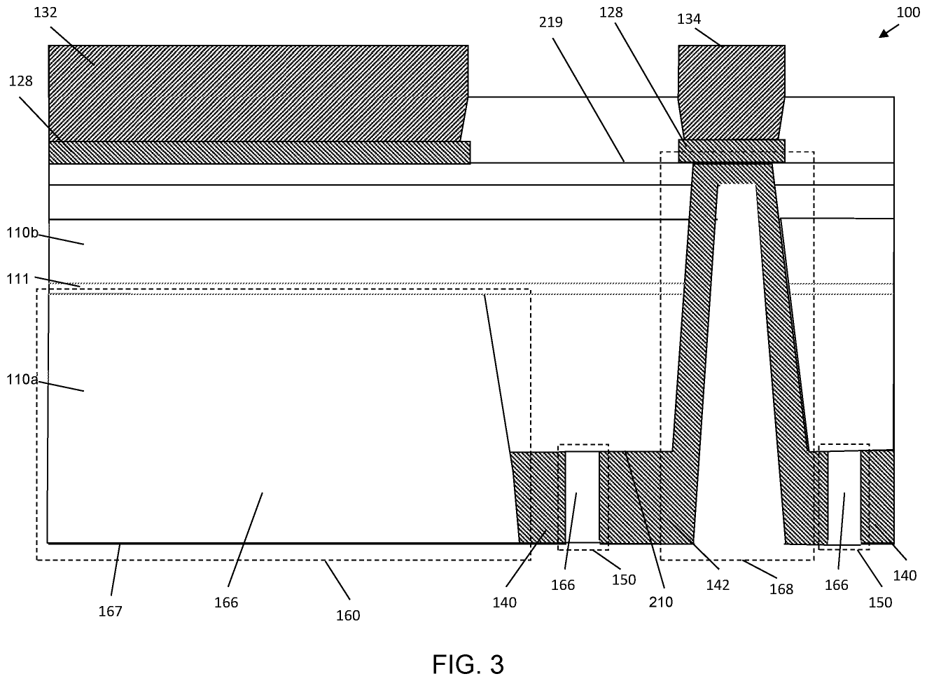

In an embodiment, and referring also to FIGS. 2 and 3, which are cross sectional views of the device of FIG. 1 along lines 2-2 and 3-3, respectively, semiconductor substrate 110 includes a top substrate surface 219 and a bottom substrate surface 210. Semiconductor substrate 110 includes silicon (Si). Configured as an SOI substrate, substrate 110 includes an insulation layer 111 formed within the body of substrate 110. Where semiconductor substrate 110 is Si, insulation layer 111 includes silicon dioxide (SiO₂) layer. The portion of semiconductor substrate 110 located below insulation layer 111 (as viewed in FIG. 2 and labeled 110a) represents a bulk silicon portion of substrate 110. The portion of semiconductor substrate 110 located above insulation layer 111 (as viewed in FIG. 2 and labeled 110b) represents the device layer of substrate 110 over which buffer layer 214, channel layer 216, channel 217 and other devices, components and conductive structures are formed.

In this SOI substrate 110 configuration, the incorporation of insulation layer 111 into device 100 can improve the performance of devices formed over a surface of semiconductor substrate 110 by reducing parasitic capacitances within substrate 110. The SOI configuration of device 100 can realize additional benefits such as eliminating substrate leakage, reducing cross talk between circuit components, and ultimately increase the electrical performance of device formed over such substrates.

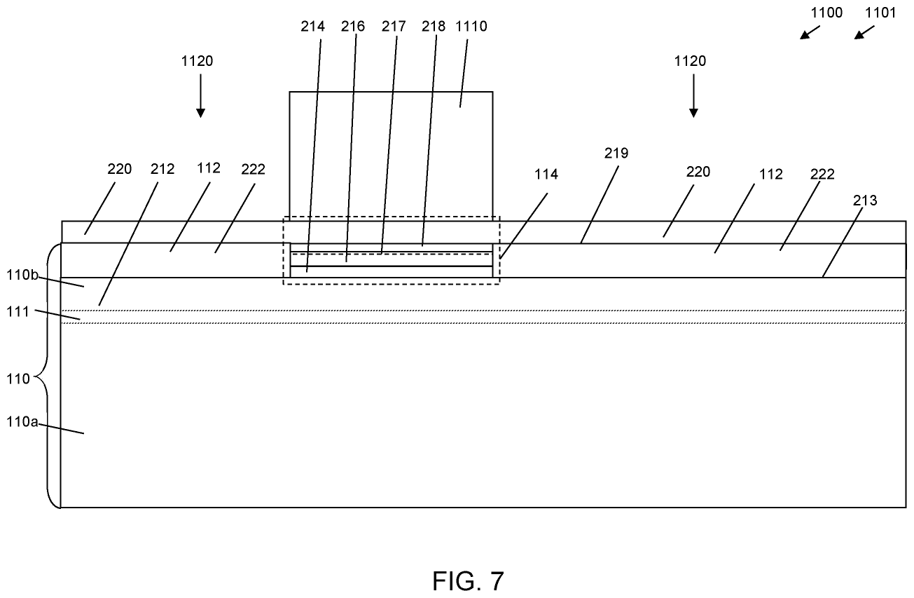

According to an embodiment, and as will be explained more fully in connection with FIG. 2, semiconductor substrate 110 (and, specifically, portion 110b of semiconductor substrate 110) includes isolation region(s) 112 that separate the one or more active areas 114 that may contain transistor(s) 120 from other nearby active area(s), thus isolating individual transistors 120 from one another. As will be detailed further in the descriptions of FIG. 7 and method step 1100, isolation region(s) 112 may be created by etching or ion bombardment of portions of the top surface 219 of portion 110b of substrate 110, or other suitable technique(s).

Transistor 120 is the chief active component in device 100. Transistor 120 includes first and second current-conducting electrodes, where the current-conducting electrodes are spatially and electrically separated by a variable conductivity channel. For example, transistor 120 may comprise one or more field effect transistor(s) including but not limited to metal-oxide semiconductor transistors (MOSFET's), metal-semiconductor field effect transistors (MESFET's), high electron-mobility transistors (HEMT's), lateral-diffused metal-oxide semiconductor transistors (LDMOS), or other suitable field effect transistors (FETs) or bipolar junction transistors (BJT's). In FET embodiments, transistor 120 may include a drain (first current-conducting electrode), a source (second current-conducting element), and a gate (control electrode). In other embodiments, transistor 120 may include bipolar junction transistors (BJT's), heterojunction bipolar transistors (HBT's), or other suitable bipolar transistors. Descriptions denoted “drain”, “source,” and “gate” herein do not limit the inventive subject matter to FETs, as the drain, source, and gate of a FET are analogous to the collector, emitter, and base of a bipolar transistor.

According to an embodiment and when implemented as a FET, transistor 120 includes a plurality of electrodes that include a drain electrode 122 (first current-conducting electrode), a source electrode 124 (second current-conducting electrode), and a gate electrode 126 (control electrode). Drain electrode 122 and source electrode 124 are formed over substrate 110 within active region 114. Device 100 also includes interconnect metallization 128 or other appropriate conductors that electrically couple drain electrode 122, source electrode 124, and gate electrode 126 to electrical circuit nodes in circuitry that is electrically coupled to transistor 120.

According to an embodiment, one or more inductors 130 and/or transmission lines 132 (first conductive features) are formed over semiconductor substrate 110 and may be electrically coupled to at least one of drain electrode 122, source electrode 124, or gate electrode 126. In an embodiment, inductor 130 may comprise a rectangular spiral inductor or a round spiral inductor, a meandering or serpentine inductor (not shown), or a combination of these or other types of inductors. A first conductive feature also may include a transmission line 132, according to an embodiment. In an embodiment, transmission line 132 may include but is not limited to a microstrip transmission line, a stripline transmission line (not shown), a coplanar waveguide (CPW) transmission line (not shown), a CPW transmission line with a finite ground plane, or other planar suitable transmission line structures. Descriptions denoted “inductor,” “transmission line,” and “top interconnect structure” in connection with the term “first conductive feature” 130, 132, 134 do not limit the inventive subject matter only to inductors, transmission lines, and conductive pads. It should be appreciated that, without departing from the inventive subject matter, in other embodiments, a “first conductive feature” may include other types of conductive and/or passive elements including, but not limited to, microwave couplers, branch-line combiners, power combiners, power splitters, Lange couplers, bulk acoustic wave (BAW) filters, high-pass filters, low-pass filters, band-pass filters, spiral baluns, Marchand baluns, impedance transformers, passive matching networks, antennas, bond wires, or other passive microwave structures. Conductive features such as inductor 130 and transmission line 132 may be electrically coupled to transistor 120 using first interconnect metal 128. In addition, and according to an embodiment, top interconnect structure(s) 134 may be formed using the same or different metal layer(s) as inductor 130 and transmission line 132 to create conductive structures, for example, but not limited to traces, pads, and other features used to electrically couple electrical signals from inductor 130 and/or transmission line 132 to back metal 140 and backside contact 142 (e.g., using through wafer vias 168).

In an embodiment, “second conductive features”, herein referred to as back metal 140 and backside contact 142, are coupled to bottom substrate surface 210 as shown in FIG. 2. It should be appreciated that references to “second conductive feature” denoted “back metal” and “backside contact” do not limit the inventive subject matter and in other embodiments (not shown), a “second conductive feature” may include other conductive electrical structures such as but not limited to inductors, couplers, transmission lines, antennas, baluns, bond wires, and other passive electrical or microwave structures that are coupled to the bottom substrate surface 210.

According to an embodiment, one or more first conductor-less region(s) 150 may be formed within the metal layer(s) used to create back metal 140 and backside contact 142 and the conductor-less region(s) 150 may be used to electrically isolate these conductive structures from one another. As used herein, the term “conductor-less region” means a region across a surface (e.g., bottom substrate surface 210) that lacks any conductive material, particularly conductive material that electrically couples opposite sides of such a region. In an embodiment, first conductor-less region 150 may be aligned (in the vertical direction in FIGS. 2 and 3) with one or more first conductive features (e.g., inductor 130, as shown in FIG. 2, and/or transmission line 132, as shown in FIG. 3). In other embodiments (not shown), first conductor-less region(s) 150 may be used to electrically isolate other conductive electrical structures formed over the bottom substrate surface 210, such as but not limited to inductors, couplers, transmission lines, antennas, baluns, bond wires, and other passive electrical or microwave structures formed as part of the second conductive feature from one another.

In an embodiment, and as will be explained more fully in connection with FIGS. 2 and 3, one or more cavities 160 are aligned, in the vertical direction, with one or more first conductor-less region(s) 150, where each cavity 160 extends into semiconductor substrate 110 from the bottom substrate surface 210 toward or to the top substrate surface 219. In some embodiments, each cavity 160 may be self-aligned with a first conductor-less region 150. Also, as will be explained more fully in FIGS. 2 and 3, each cavity 160 may be formed underneath one or more process layers overlying the top surface 219 of semiconductor substrate 110 and/or semiconductor layers within semiconductor substrate 110. In an embodiment, each cavity 160 may be aligned in the vertical direction with and completely overlap a first conductive feature 130, 132. In other embodiments (not shown), a cavity 160 may partially overlap a first conductive feature 130, 132. In an embodiment, and as will be described in more detail in association with FIGS. 2 and 3, a dielectric medium 166 may be disposed within at least a portion of some or all of cavities 160. According to an embodiment, one or more through wafer vias 168 may be used to electrically couple top interconnect structures 134 to back metal 140 or backside contact 142.

FIG. 2 is a cross section view of device 100 along cut line 2-2 showing further details of the device 100. According to an embodiment, device 100, as viewed along cut line 2-2, includes semiconductor substrate 110, transistor 120, first conductive feature or inductor 130, second conductive feature or back metal 140, first conductor-less regions 150, and cavity 160.

Semiconductor substrate 110 may include a top substrate surface 219, and a bottom substrate surface 210. Substrate 110 is configured as an SOI substrate with a lower portion 110a separated from an upper portion 110b (as viewed in FIG. 2) by insulation layer 111. When substrate 110 is a Si substrate, insulation layer 111 may include SiO₂. Portion 110b of semiconductor substrate 110 includes a buffer layer 214, a channel layer 216, and a barrier layer 218, which are formed in portion 110b of substrate 110 during device 100 fabrication.

In an embodiment, substrate 110 includes an upper surface 213 and is formed from silicon (Si). Buffer layer 214 is formed on upper surface 213 of substrate 110. Buffer layer 214 may include one or more group III-N semiconductor layers and is supported by portion 110b of substrate 110. Buffer layer 214 may be a multi-layer structure, where each of the semiconductor layers of buffer layer 214 may include an epitaxially grown group III nitride eptiaxial layer, for example. The group-III nitride epitaxially grown layers that make up buffer layer 214 may include nitrogen (N)-polar (i.e. N-face) or gallium (Ga)-polar (i.e. Ga-face) material, for example. In other embodiments, the semiconductor layer(s) of buffer layer 214 may not be epitaxially grown.

Buffer layer 214 may include at least one AlGaN mixed crystal layer having a composition denoted by Al_{X}Ga_{1-X}N with an aluminum mole fraction, X, that can take on values between 0 and 1. The total thickness of buffer layer 214 with all of its layers may be between about 200 angstroms and about 100,000 angstroms although other thicknesses may be used. A limiting X value of 0 yields pure GaN while a value of 1 yields pure aluminum nitride (AlN). In an embodiment, buffer layer 214 may include a nucleation region comprised of AlN. The nucleation region starts at the interface between the substrate 110 and buffer layer 214 and extends about 100 angstroms to about 2000 angstroms into buffer layer 214. Buffer layer 214 may include additional Al_{X}Ga_{1-X}N layers formed over the nucleation region. The thickness of the additional Al_{X}Ga_{1-X}N layer(s) may be between about 100 angstroms and about 50,000 angstroms though other thicknesses may be used. In an embodiment, the additional Al_{X}Ga_{1-X}N layers may be configured as GaN (X=0) where the Al_{X}Ga_{1-X}N that is not intentionally doped (NID). Alternatively, the additional Al_{X}Ga_{1-X}N layers may be configured as one or more GaN layers where the one or more GaN layers are intentionally doped with dopants that may include iron (Fe), chromium (Cr), carbon (C) or other suitable dopants that render buffer layer 214 substantially insulating or high resistivity. The dopant concentration may be between about 10¹⁷ and 10¹⁹ cm⁻³ though other higher or lower concentrations may be used. The additional Al_{X}Ga_{1-X}N layers may be configured with X=0.01 to 0.10 where the Al_{X}Ga_{1-X}N is NID or, alternatively, where the Al_{X}Ga_{1-X}N is intentionally doped with Fe, Cr, C, a combination of these, or other suitable dopant species. In other embodiments, the additional layers may be configured as a superlattice where the additional layers include a series of alternating NID or doped Al_{X}Ga_{1-X}N layers where the value of X takes a value between 0 and 1. In still other embodiments, buffer layer 214 may include one or more indium gallium nitride (InGaN) layers, with composition denoted In_{Y}Ga_{1-Y}N, where Y, the indium mole fraction, may take a value between 0 and 1. The thickness of the InGaN layer(s) may be between about 10 angstroms and about 2000 angstroms though other thicknesses may be used.

In an embodiment, channel layer 216 is formed over buffer layer 214. Channel layer 216 may include one or more group III-N semiconductor layers and is supported by buffer layer 214. Channel layer 216 may include an Al_{X}Ga_{1-X}N layer where X takes on values between 0 and 1. In an embodiment, channel layer 216 is configured as GaN (X=0) although other values of X may be used without departing from the scope of the inventive subject matter. The thickness of channel layer 216 may be between about 50 angstroms and about 10,000 angstroms, though other thicknesses may be used. Channel layer 216 may be NID or, alternatively, may include Si, Ge, C, Fe, Cr, or other suitable dopants. The dopant concentration may be between about 10¹⁶ and about 10¹⁹ cm⁻³ though other higher or lower concentrations may be used. In other embodiments, channel layer 216 may include NID or doped In_{Y}Ga_{1-Y}N, where Y, the indium mole fraction, may take a value between 0 and 1.

Barrier layer 218 is formed over channel layer 216 in accordance with an embodiment. Barrier layer 218 may include one or more group III-N semiconductor layers and is supported by channel layer 216. Barrier layer 218 may have a larger bandgap and/or larger spontaneous polarization than channel layer 216 and, when barrier layer 218 is over channel layer 216, a channel 217 is created in the form of a two-dimensional electron gas (2-DEG) within channel layer 216 adjacent the interface between channel layer 216 and barrier layer 218. In addition, tensile strain between barrier layer 218 and channel layer 216 may cause additional piezoelectric charge to be introduced into the 2-DEG and channel 217. Barrier layer 218 may be a multi-layer structure, where the first layer of barrier layer 218 may include at least one NID Al_{X}Ga_{1-X}N layer where X takes on values between 0 and 1. In some embodiments, X may take a value of 0.1 to 0.35, although other values of X may be used. The thickness of the first layer of barrier layer 218 may be between about 50 angstroms and about 1000 angstroms though other thicknesses may be used. Barrier layer 218 may be NID or, alternatively, may include Si, Ge, C, Fe, Cr, or other suitable dopants. The dopant concentration may be between about 10¹⁶ and 10¹⁹ cm⁻³ though other higher or lower concentrations may be used. There may be an additional AlN interbarrier layer (not shown) formed between channel layer 216 and barrier layer 218, in some embodiments. The AlN interbarrier layer may introduce additional spontaneous and piezoelectric polarization, increasing the channel charge and improving the electron confinement of the resultant 2-DEG. In other embodiments, barrier layer 218 may include one or more indium aluminum nitride (InAlN) layers, denoted In_{Y}Al_{1-Y}N, where Y, the indium mole fraction, may take a value between about 0.1 and about 0.2 though other values of Y may be used. In the case of using MAIN to form barrier layer 218, the thickness of barrier layer 218 may be between about 50 angstroms and about 2000 angstroms though other thicknesses may be used. In the case of using InAlN to form barrier layer 218, the InAlN may be NID or, alternatively, may include Si, Ge, C, Fe, Cr, or other suitable dopants. The dopant concentration may be between about 10¹⁶ cm⁻³ and about 10¹⁹ cm⁻³ though other higher or lower concentrations may be used.

A cap layer (not shown) may be formed over barrier layer 218. The cap layer presents a stable surface for semiconductor substrate 110 and serves to protect the top substrate surface 219 from chemical and environmental exposure incidental to wafer processing. The cap layer may include one or more group III-N semiconductor layers and is supported by barrier layer 218. In an embodiment, the cap layer includes GaN. The thickness of the cap layer may be between about 5 angstroms and about 100 angstroms though other thicknesses may be used. The cap layer may be NID or, alternatively, may include Si, Ge, C, Fe, Cr, or other suitable dopants. The dopant concentration may be between about 10¹⁶ cm⁻³ and 10¹⁹ cm⁻³ though other higher or lower concentrations may be used.

Without departing from the scope of the inventive subject matter, it should be appreciated that the choice of materials and arrangement of layers to form semiconductor substrate 110 is exemplary and the function and operation of the various layers may be combined and may change depending on the materials used in any specific embodiment. In other embodiments using N-polar materials (not shown), channel layer 216 may be disposed over barrier layer 218 to create a 2-DEG and channel directly underneath an optional GaN cap and control electrode 126. Still further embodiments may include semiconductor layers used to form semiconductor substrate 110 formed from other group-III nitride materials including, but not limited to AlN, AlGaN, InGaN.

One or more isolation region(s) 112 may be formed within semiconductor substrate 110 to define an active area 114 proximate to top substrate surface 219, according to an embodiment. Isolation region(s) 112 may be formed via an implantation procedure configured to damage the epitaxial and/or other semiconductor layers to create high resistivity semiconductor regions 222 of semiconductor substrate 110, rendering semiconductor substrate 110 high resistivity or semi-insulating in high resistivity semiconductor regions 222 while leaving the crystal structure intact in the active area 114. In various embodiments, high resistivity semiconductor regions 222 may include AlGaN, AlN, InGaN, or other group-III nitrides. In other embodiments (not shown), isolation region(s) 112 may be formed by removing one or more of the epitaxial and/or other semiconductor layers of semiconductor substrate 110 in areas corresponding to the isolation region(s) 112, thus removing channel 217 in the isolation region(s) 112, rendering the remaining layers of semiconductor substrate 110 semi-insulating and leaving behind active area 114 “mesas” surrounded by high resistivity or semi-insulating isolation region(s) 112.

As was discussed in conjunction with the description of FIG. 1 in part, transistor 120 is formed over the top surface 219 of semiconductor substrate 110. Transistor 120 may include active region 114 within semiconductor substrate 110, drain electrode 122, source electrode 124 (current-conducting electrodes), gate electrode 126, first dielectric layer 220, second dielectric layer 224, and first interconnect metal 128.

In an embodiment, first dielectric layer 220 may be formed over active area 114 and isolation region 112. According to an embodiment, and as will be described later in conjunction with the method depicted in FIG. 7 describing fabrication step 1100, first dielectric layer 220 may include one or more substantially insulating dielectric layers. In an embodiment, first dielectric layer 220 may include silicon nitride (SiN), silicon dioxide (SiO₂), silicon oxynitride (SiON), hafnium oxide (HfO₂), or other insulating materials. In other embodiments, first dielectric layer 220 may include thermally conductive materials such as diamond, poly-diamond, AlN, BN, SiC, or other high thermal conductivity substantially insulating or semi insulating materials. In an embodiment, first dielectric layer 220 has thickness values in the range of about 100 angstroms to about 3000 angstroms, though other thickness values may be used, depending on the thermal conductivity of the material used to realize first dielectric layer 220.

In an embodiment, current-conducting electrodes such as source electrode 124 and drain electrode 122 may be formed over and in contact with semiconductor substrate 110 adjacent gate electrode 126 in active area 114. According to an embodiment, source electrode 124 and drain electrode 122 are created in openings made in first dielectric layer 220.

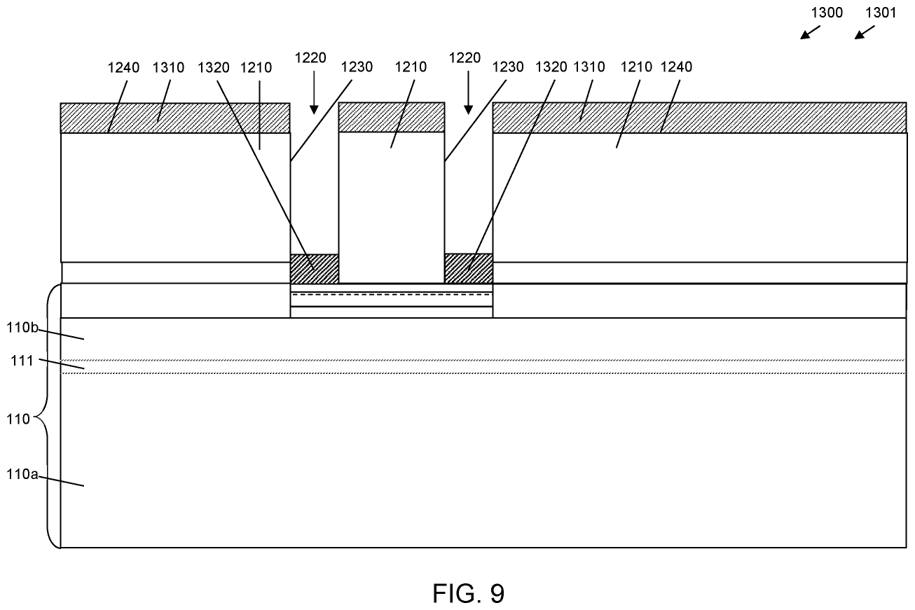

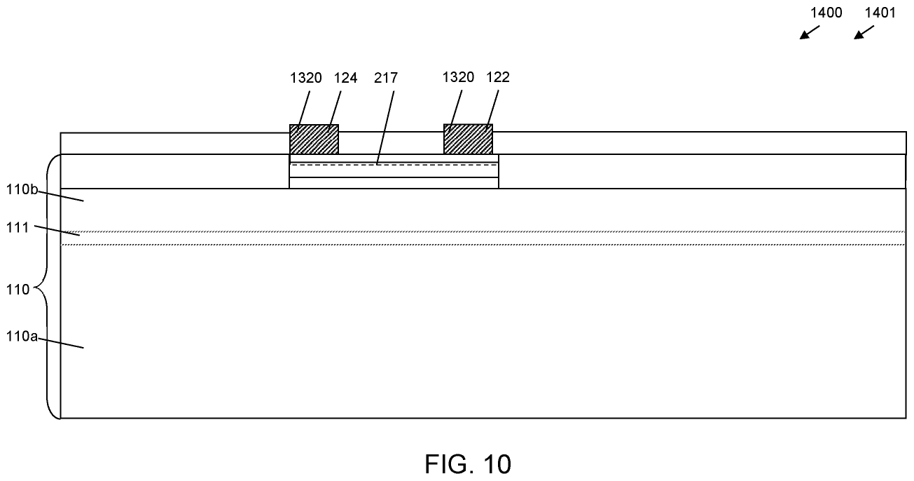

In an embodiment, drain electrode 122 and source electrode 124 (current-conducting electrodes) are created from ohmic contacts to channel 217. As will be described later, in an embodiment of a method for forming drain electrode 122 and source electrode 124, as depicted and described in conjunction with FIGS. 9 and 10 and steps 1300 and 1400 below, low work function materials may be combined with high conductivity materials and refractory barrier materials in a metal stack to form drain electrode 122 and source electrode 124 coupled to channel 217, according to an embodiment. Drain electrode 122 and source electrode 124 may be formed over and in contact with top substrate surface 219, according to an embodiment. In other embodiments, source electrode 124 and drain electrode 122 may be recessed below top substrate surface 219 and extend partially into barrier layer 218. In still other embodiments, ion implantation of Si, Ge, or other appropriate dopants, may be used to form ohmic contact to the channel 217.

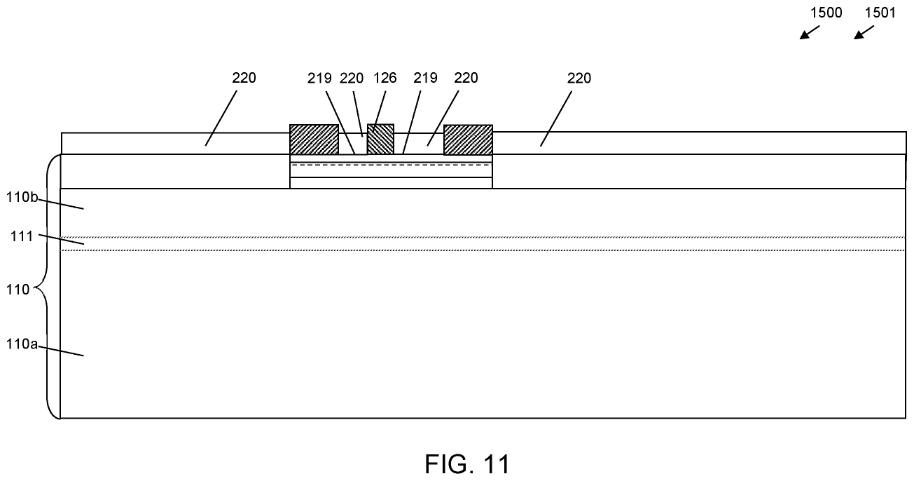

In an embodiment, gate electrode 126 (control electrode) is formed over semiconductor substrate 110 in active region 114. Gate electrode 126 is electrically coupled to the channel 217 through upper surface 219 and barrier layer 218. Changes to the electric potential on gate electrode 126 shift the quasi Fermi level for barrier layer 218 compared to the quasi Fermi level for channel layer 216 and thereby modulate the electron concentration in channel 217 within the portion of semiconductor substrate 110 under gate electrode 126. In an embodiment, gate electrode 126 is configured as a Schottky gate and may be formed over and directly in contact with top substrate surface 219 using a Schottky material layer and a conductive metal layer. A conductive, low stress metal is deposited over the Schottky material layer to form gate electrode 126, in an embodiment. Gate electrode 126 may have a square cross-sectional shape as shown or may have a T-shaped cross section with a vertical stem over semiconductor substrate 110 and a wider portion over the vertical stem in other embodiments. In other embodiments, gate electrode 126 may be recessed through top substrate surface 219 and extend partially into barrier layer 218, increasing the electrical coupling of gate electrode 126 to channel 217 through barrier layer 218. As will be described later, in an embodiment of a method for forming gate electrode 126, as depicted in FIG. 11 and described in conjunction with step 1500 below, Schottky or other suitable materials may be combined with highly conductive materials in a metal stack to form a gate electrode 126 for a low loss gate electrode electrically coupled to channel 217, according to an embodiment. In other embodiments, gate electrode 126 may be formed over a gate dielectric or gate oxide forming a metal-insulator-semiconductor (MIS) junction or metal oxide semiconductor (MOS) junction, electrically coupled to the channel 217 through the gate dielectric or gate oxide layer.

In an embodiment, first interconnect metal 128 may be electrically coupled to transistor 120. In an embodiment, first interconnect metal 128 may be formed over top substrate surface 219 and first dielectric layer 220 and electrically coupled to one or more of drain electrode 122, source electrode 124, and/or gate electrode 126. First interconnect metal 128 may include an adhesion layer and a primary conductive layer in contact with the adhesion layer. The adhesion layer may be selected from one or more of titanium (Ti), titanium tungsten (TiW), Cr, or other suitable low-stress material(s). The adhesion layer may have a thickness between about 50 angstroms and about 1 microns, although other thicknesses may be used. The conductive layer may be selected from one or more of gold (Au), aluminum (Al), silver (Ag), or copper (Cu). The conductive layer may have a thickness of between about 0.1 and about 20 microns though other thicknesses may be used.

In an embodiment, inductor 130 (a first conductive feature) may be electrically coupled to first interconnect metal 128 that is electrically coupled to transistor 120. Metallization used to form inductor 130 may include an adhesion layer disposed over first dielectric 220 and a primary conductive layer disposed over the adhesion layer. The adhesion layer may be selected from one or more of Ti, TiW, Cr, or other suitable low-stress material(s). The adhesion layer may have a thickness between about 50 angstroms and about 1 micron, although other thicknesses may be used. The conductive layer may be selected from one or more of Au, Al, Ag, or Cu. The conductive layer may have a thickness of between about 0.1 and about 20 microns though other thicknesses may be used. It should be appreciated that the configuration and arrangement of inductor 130 (first conductive feature) with respect to first interconnect metal 128 is exemplary and may be re-arranged according to the specific design of device 100. For example, in other embodiments, inductor 130 may be formed under first interconnect metal 128 (i.e., between first interconnect metal 128 and the top substrate surface 219). In still other embodiments, inductor 130 may be formed using the same metallization layer as first interconnect metal 128. Further, although inductor 130 is shown as being formed from a single metal layer, alternate embodiments of inductors may be formed from multiple metal layers (e.g., multiple coils in multiple metal layers) that are interconnected with conductive vias.

In an embodiment, back metal 140 and/or backside contact 142 (a second conductive feature) may include an adhesion layer that contacts bottom substrate surface 210 and a primary conductive layer that contacts the adhesion layer. The adhesion layer may be selected from one or more of Ti, TiW, Cr, or other suitable low-stress material. The adhesion layer may have a thickness between about 50 angstroms and about 2 microns, although other thicknesses may be used. The conductive layer may be selected from one or more of Au, Al, Ag, Cu, a combination of these, or other conductive material. The conductive layer may have a thickness of between about 0.1 and about 50 microns though other thicknesses may be used. In an embodiment, back metal 140 and backside contact 142 are etched to expose bottom substrate surface 210 and form first conductor-less region(s) 150 in the etched regions.

In an embodiment, cavity 160 is formed in semiconductor substrate 110, adjacent (i.e., next to but not underlying) transistor 120. According to an embodiment, cavity 160 is partially defined by an inner cavity surface 262 with inner cavity dimension 263 that defines an upper surface of cavity 160, a cavity wall 264, subtended by lower substrate surface 210 at a cavity wall angle 265, that defines the side wall of cavity 160, and one of conductor-less region(s) 150 with outer cavity dimension 267 that defines the opening of cavity 160 within lower substrate surface 210. Inner cavity dimension 263 may be defined by etching into semiconductor substrate 110 and may be between about 5 microns and about 1000 microns although other suitable dimensions may be used. The cavity wall angle 265 subtended by cavity wall 264 and lower substrate surface 210 may be between about 80 degrees and about 150 degrees in an embodiment. In other embodiments, cavity wall angle 265 may be between about 90 degrees and about 110 degrees, though other angles may be used. Outer cavity dimension 267 may be defined by etching into semiconductor substrate 110 and may be between about 5 microns and about 1000 microns though other suitable dimensions may be used. A cavity height 268 defined by the inner cavity dimension 263, cavity wall angle 265, outer cavity dimension 267, and the thickness of back metal 140 may be between about 1 and about 50 microns though other suitable dimensions may be used. In various embodiments, a depth of cavity 160 may range from 50 um to 200 um, though in other embodiments the depth of cavity 160 may be at least partially determined by a final substrate 110 thickness after back grinding. In an embodiment, cavity 160 may extend vertically into substrate 110 (and, specifically, region 110a of substrate 110 below insulation layer 111) from the bottom substrate surface 210. In some embodiments, cavity 160 may terminate at the bottom surface 113 of insulation layer 111.

In this configuration, in which cavity 160 terminates at the bottom surface 113 of insulation layer 111, the portion 115 of portion 110b of semiconductor substrate 110 that remains between inductor 130 and insulation layer 111 provides structural strength to the region of device 100 underlaying inductor 130. This is in contrast to other approaches for forming cavity 160 in which cavity 160 extends throughout the entirety of semiconductor substrate 110 such that the cavity 160 terminates at a surface of one or more of the layers formed over semiconductor substrate 110 such as second dielectric layer 224, first dielectric layer 220, and the like.

Without departing from the scope of the inventive subject matter, in other embodiments (not shown), cavity 160 may underlie a portion of transistor 120. In these embodiments, at least a portion of drain 122, source 124, and/or gate 126 act as the first conductive region that overlies and is aligned with cavity 160.

In an embodiment, dielectric medium 166 may fill cavity 160. In an embodiment, dielectric medium 166 has a lower dielectric constant than that of semiconductor substrate 110. For example, the dielectric constant of semiconductor substrate 110 may be in a range of about 9 to about 14, and the dielectric constant of dielectric medium 166 may be in a range of about 1 to about 8, in an embodiment. In alternate embodiments, the dielectric constants of semiconductor substrate 110 and dielectric medium 166 may be lower or higher than the above-given ranges. According to an embodiment, the term “less than,” when used to describe a relative relationship between the dielectric constants of host substrate 212 and dielectric medium 166 means that the dielectric constant of the dielectric medium 166 is about 90 percent or less of the dielectric constant of the host substrate 212, or that the dielectric constant of the dielectric medium 166 is about 50 percent or less of the dielectric constant of the host substrate 212.

In an embodiment, dielectric medium 166 is formed using one or more of benzocyclobutene (BCB), polyimide, epoxy, spin-on glass, a combination of these or other suitable dielectric materials. In other embodiments, dielectric 166 is air. In an embodiment, dielectric medium 166 fills cavity 160 and conductor-less region(s) 150 terminating on a dielectric medium surface 167. In other embodiments, dielectric medium 166 partially fills cavity 160 and/or conductor-less region 150. In these embodiments, a void (not shown) may be left between the plane of back metal surface 242 and dielectric medium surface 167 leaving air as the dielectric medium in the unfilled portion of cavity 160 and/or conductor-less region 150.

In an embodiment, through wafer via(s) 168 are formed in semiconductor substrate 110, adjacent transistor 120. In an embodiment, each through wafer via 168 is formed by etching host substrate 212 and overlying semiconductor layers in isolation region 112 to expose first interconnect metal 128 and/or top interconnect structure(s) 134. In other embodiments, through wafer via(s) 168 are formed in semiconductor substrate 110, underneath transistor 120 and vertically aligned to drain electrode 122 or source electrode 124. In these embodiments, each through wafer via 168 is formed by etching host substrate 212 and overlying semiconductor layers in isolation region 112 to expose at least a portion of drain electrode 122, source electrode 124, first interconnect metal 128 and/or top interconnect structure(s) 134. Metal used to form back metal 140 and/or backside contact 142 may be used to fill or coat the sidewalls of the inside of through wafer via 168 and to contact drain electrode 122, source electrode 124, first interconnect metal 128 and/or top interconnect structure(s) 134 to provide electrical coupling between drain electrode 122, source electrode 124, first interconnect metal 128, top interconnect structure(s) 134, back metal 140 and/or backside contact 142.

FIG. 3 is a cross sectional view of device 100 along cut line 3-3 of FIG. 1 showing further aspects of the device 100. More particularly, FIG. 3 shows a view of device 100 with a partial view of transmission line 132, and the conductive connection between top interconnect structure 134 and backside contact 142, according to an embodiment. In an embodiment, transmission line 132 is aligned in the vertical direction with cavity 160. Cavity 160 is filled with dielectric medium 166 according to an embodiment. In an embodiment, the connection of first interconnect metal 128 and top interconnect structure 134 to backside contact 142 may be accomplished using through wafer via 168 to electrically couple backside contact 142 to first interconnect metal 128 and top interconnect structure 134 using the metal layer that forms both back metal 140 and backside contact 142. Conductor-less regions 150 electrically isolate backside contact 142 from back metal 140, according to an embodiment. In an embodiment, dielectric medium 166 may fill conductor-less regions 150 within cavity 160 and in conductor-less regions 150 that isolate back metal 140 from backside contact 142.

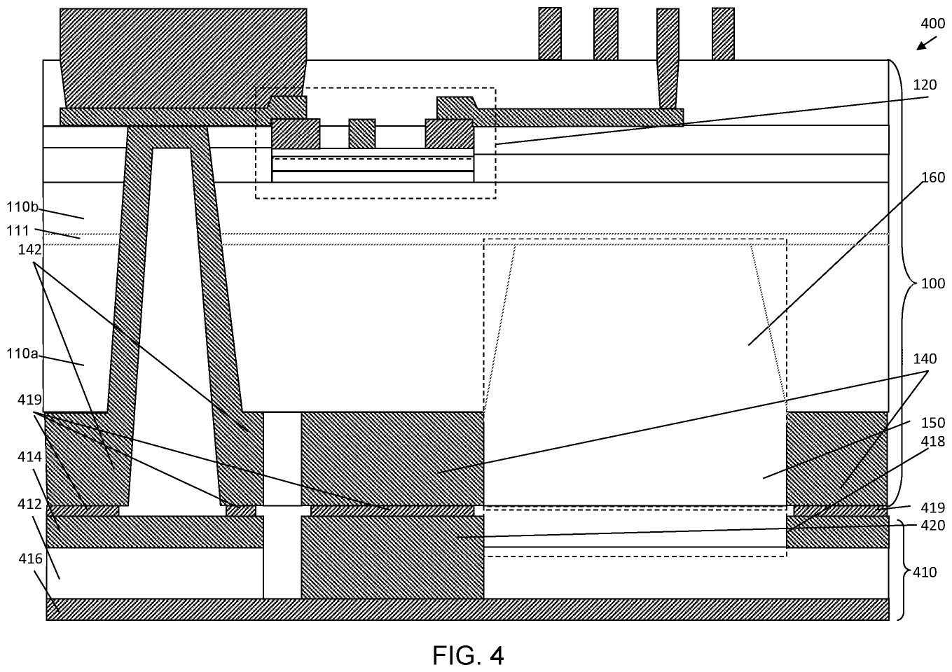

FIG. 4 is a cross sectional view of electronic assembly 400 showing other aspects of the inventive subject matter according to an embodiment. In an embodiment, electronic assembly 400 may include device 100 of FIGS. 1-3, one or more printed circuit board(s) (PCB's) 410 and a flange 420. In an embodiment, device 100 is coupled to PCB 410.

In an embodiment, PCB 410 may include one or more PCB dielectric region(s) 412, one or more PCB top conductor(s) 414, and one or more PCB bottom conductor(s) 416. In an embodiment, PCB dielectric 412 may include, but is not limited to a polytetrafluoroethylene (PTFE) (random glass or ceramic) composite laminate, ceramic, alumina, beryllium oxide (BEO), a combination of these and/or other suitable dielectric substrates. In an embodiment, PCB top conductor 414 may be patterned to accommodate backside contact 142 of device 100. For example, PCB top conductor 414 may be patterned to form a PCB conductor-less region 418 that aligns in the vertical direction with conductor-less region 150 under cavity 160 that is vertically aligned with inductor 130. PCB top conductor 414 may be bonded to backside contact 142 and/or back metal 140 using an appropriate solder or other bonding material 419. PCB(s) 410 may be mounted to a suitable package or module (not shown).

In an embodiment, flange 420 may be bonded to back metal 140 of device 100 in using solder or other bonding material 419. In an embodiment, flange 420 is mounted to back metal 140 vertically below transistor 120 to provide a thermal heat path that allows heat to flow from transistor 120 through host substrate 212 to an appropriate heat sink or other thermal reservoir coupled to flange 420 (not shown).

It should be appreciated that, because inductor 130 is backed by an underlying cavity 160 that is optionally filled with dielectric medium 166, as shown in FIGS. 1-4, inductor 130 has a higher quality factor (Q), lower capacitance, and a higher self-resonance frequency than conventional inductors that lack such an underlying cavity. Likewise, characteristic impedances for transmission line 132 backed by cavity 160 containing dielectric 166 is higher than conventional transmission lines that lack an underlying cavity.

The Q of inductor 130 and/or transmission line 132 increases because, in an embodiment, dielectric medium 166 may include an insulating material (e.g. BCB) that has extremely high resistivity (e.g. 10⁵-10¹⁰ ohm-cm) compared to Si (e.g. 10-5000 ohm-cm). Therefore, dielectric losses and eddy current losses associated with inductor 130 and/or transmission line 132 decrease due to the reduction in semiconductor substrate 110 volume directly underneath each of inductor 130 and transmission line 132 and the Q of inductor 130 and/or transmission line 132 increases.

The capacitance between inductor 130 of FIGS. 1-3 and a voltage reference plane or ground plane below cavity 160 reduces because of the lower dielectric constant of dielectric medium 166 compared to semiconductor substrate 110. The voltage reference plane or ground plane may be provided by a package or flange that device 100 is mounted to (e.g., flange 420), or by a conductor of PCB 410 (e.g., PCB top conductor 414 or PCB bottom conductor 416), when used in an electronic assembly such as in FIG. 4 or other circuitry (not shown). In addition, the lower capacitance of inductor 130 increases its self-resonance frequency. The higher self-resonance frequency increases the potential operating frequency of inductor 130 compared to conventional inductors without cavity 160. Likewise, the lower capacitance of transmission line 132 also raises its characteristic impedance. The characteristic impedance of transmission line 132 can be approximated by the square root of the ratio of inductance per unit length divided by capacitance per unit length. Lowering the capacitance per unit length of transmission line 132 using the lower dielectric constant of dielectric medium 166 within cavity 160 raises the characteristic impedance of transmission line 132.

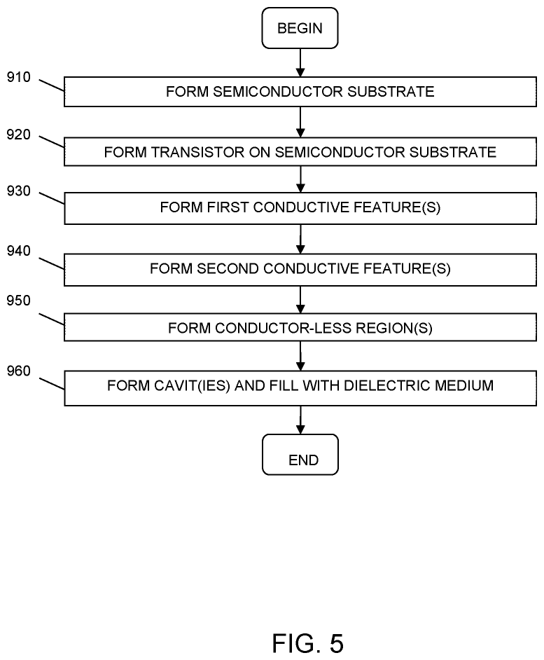

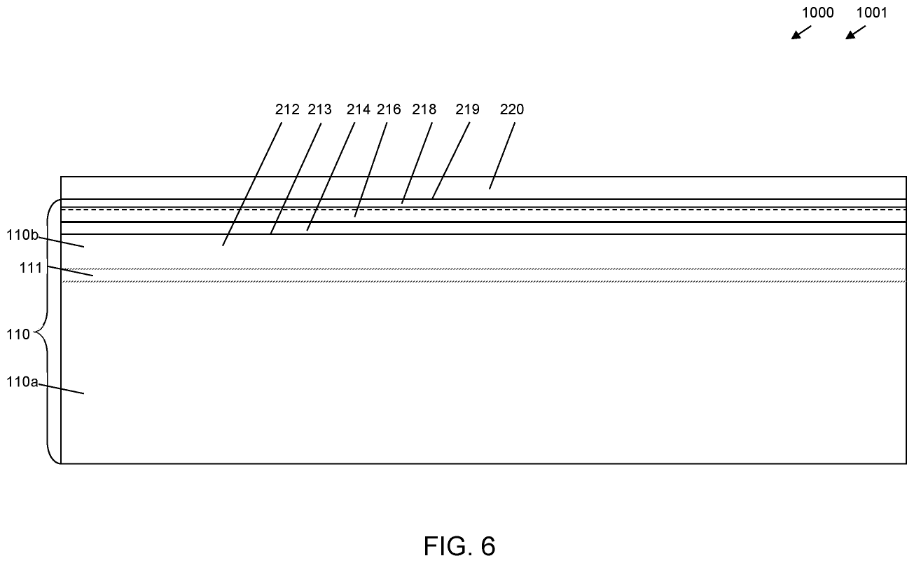

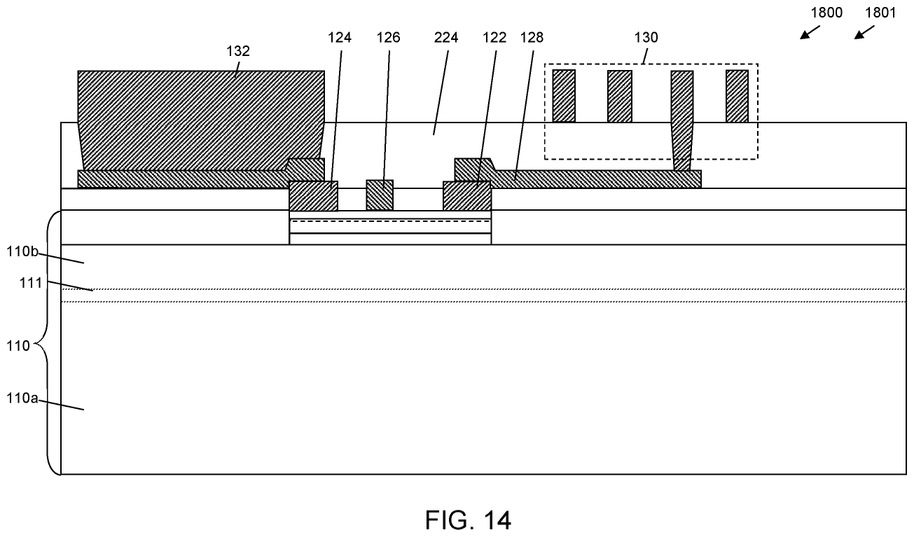

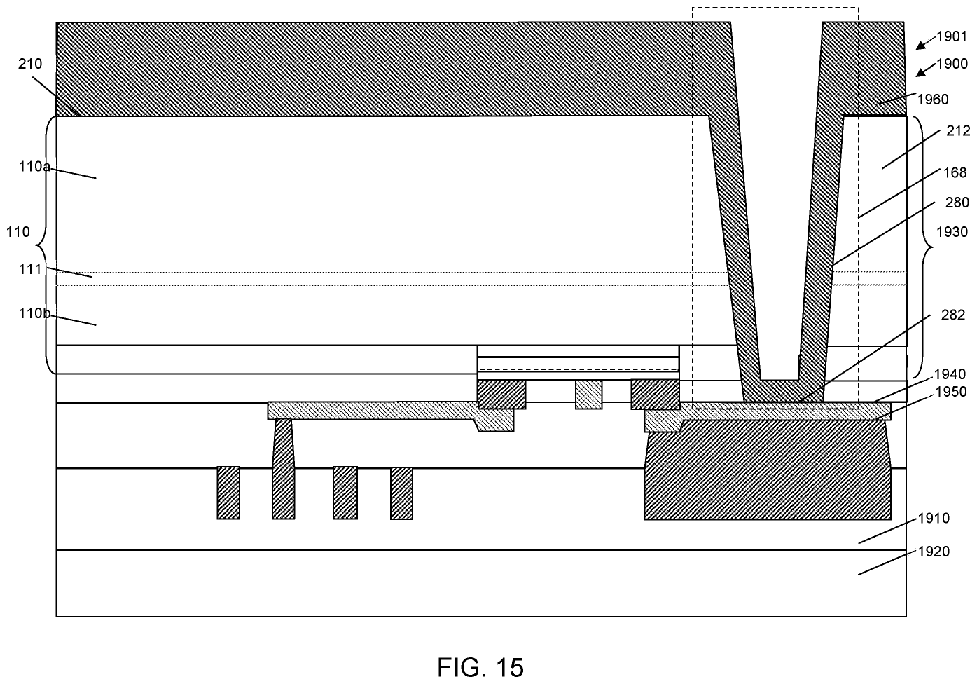

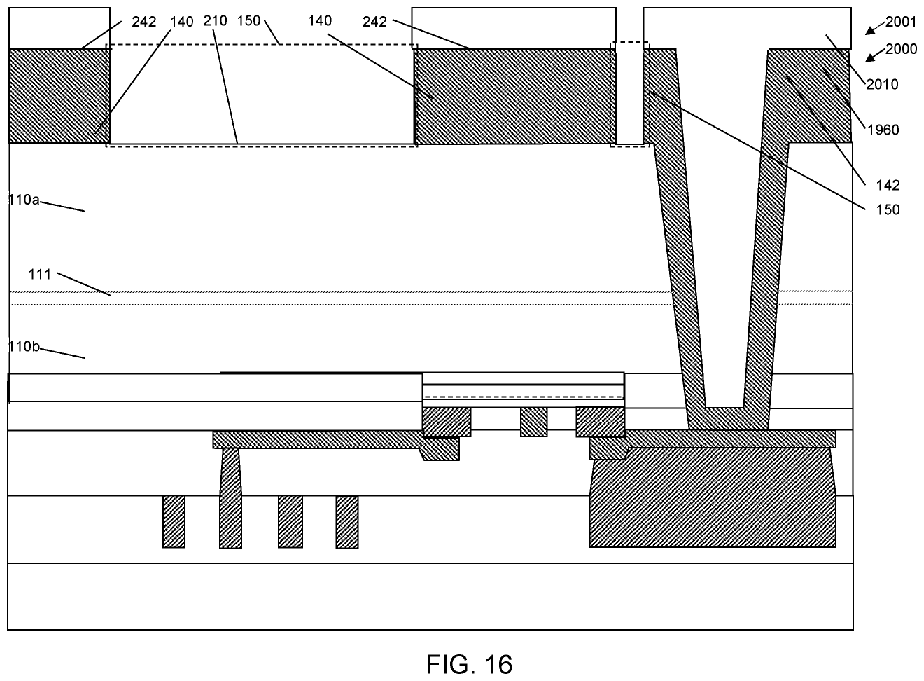

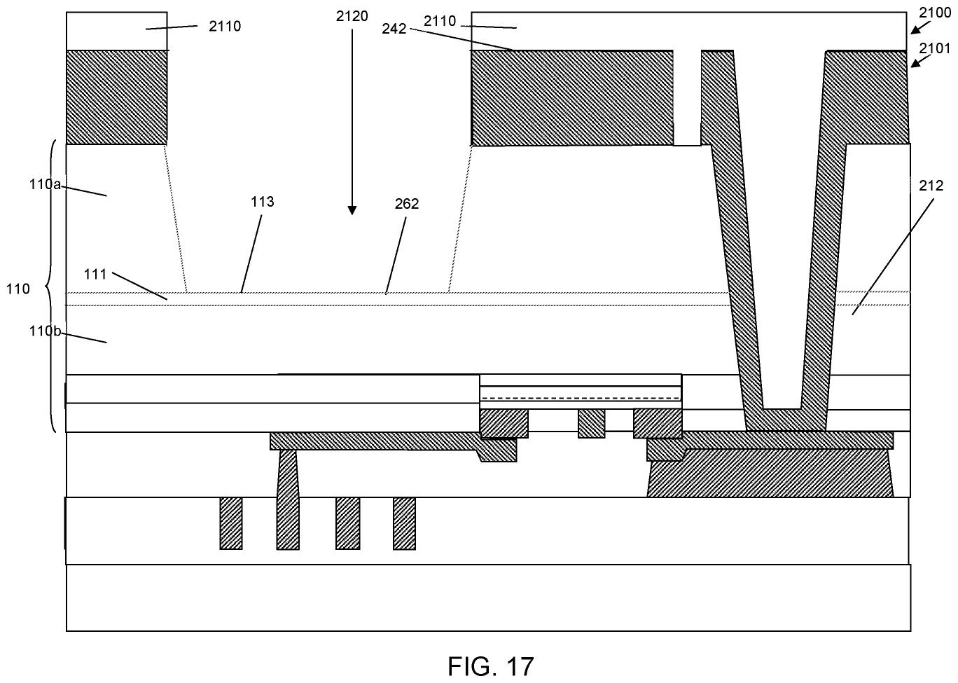

FIG. 5 is a simplified flowchart depicting a method of fabricating a device (e.g., device 100), according to an embodiment. In block 910, a semiconductor substrate (e.g., substrate 110) is formed as will be described in detail in connection with FIG. 6 and step 1000. In block 920, a transistor (e.g., transistor 120) is formed as will be described in FIGS. 7-13 and steps 1100-1700. In block 930, one or more first conductive features (e.g., inductor 130 and or transmission line 132) are formed as will be described in FIG. 14 and step 1800. In block 940, one or more second conductive features (e.g., back metal 140 and backside contact(s) 142) are formed as will be described in FIG. 15 and step 1900. In block 950, one or more conductor-less regions (e.g., regions 150) are formed as will be described in FIG. 16 and step 2000. In block 960, one or more cavities (e.g., cavities 160) are formed and filled with dielectric medium (e.g., dielectric medium 166) as will be described in FIGS. 17-19 and steps 2100-2300.

FIGS. 6-20 display simplified cross sectional views of a series of fabrication steps 1000-2400 for forming device 100 of FIG. 1, according to an embodiment. Referring first to FIG. 6, a step 1000 of the method includes forming substrate 110, which comprises a substrate 110 separated into lower portion 110a and portion 110b by a thin insulation layer 111. In embodiment where semiconductor substrate 110 is a Si substrate, insulation layer 111 may include SiO₂. First dielectric layer 220 is disposed over top substrate surface 219, according to an embodiment. In an embodiment, forming semiconductor substrate 110 includes providing forming insulation layer 111 within semiconductor substrate 110 to define lower portion 110a and 110b. Forming semiconductor substrate 110 further may include depositing buffer layer 214, channel layer 216, barrier layer 218, and a cap layer (not shown) over and on top of portion 110b of semiconductor substrate 110 to form semiconductor substrate 110. According to an embodiment, buffer layer 214 may be deposited on or over an upper surface 213 of semiconductor substrate 110. Buffer layer 214 may include one of GaN, AlGaN, InGaN, a combination of these, or other suitable materials. According to an embodiment, channel layer 216 may be deposited on or over an upper surface of buffer layer 214. Channel layer 216 may include one of GaN, AlGaN, InGaN, a combination of these, or other suitable materials. According to an embodiment, barrier layer 218 may be deposited on or over channel layer 216. Barrier layer 218 may include one of AlGaN, InAlN, a combination of these or other suitable materials. According to an embodiment, a cap layer (not shown) may be deposited on or over the barrier layer 218. The cap layer may include GaN or other suitable materials. Each of buffer layer 214, channel layer 216, barrier layer 218, and the cap layer may be grown over an upper surface 213 of host substrate 212 using one of metal-organo chemical vapor deposition (MOCVD), molecular beam epitaxy (MBE), hydride-vapor phase epitaxy (HVPE) or a combination of these techniques, though other suitable techniques may be used.

According to an embodiment, the method further includes depositing a first dielectric layer 220 over top substrate surface 219. In an embodiment, first dielectric layer 220 may include one or more layers of silicon nitride, SiO₂, HfO₂, Al₂O₃, diamond, poly-diamond, AlN, BN, SiC a combination of these or other insulating materials. The total thickness of the layer(s) used to form first dielectric layer 220 may be between about 100 angstroms and about 10,000 angstroms in thickness, although other thickness values may be used. In an embodiment, first dielectric layer 220 may be formed by depositing Al₂O₃ over and in contact with semiconductor substrate 110 and then depositing SiN over the Al₂O₃ layer. In another embodiment, first dielectric layer 220 may be formed by depositing Al₂O₃ or SiN or a combination of these over and in contact with semiconductor substrate 110 and then depositing diamond, AlN, or another suitable substantially insulating material over the Al₂O₃ layer. First dielectric layer 220 may be deposited using low pressure chemical vapor deposition (LPCVD), plasma-enhanced chemical vapor deposition (PECVD), sputtering, physical vapor deposition (PVD), atomic layer deposition (ALD), catalytic chemical vapor deposition (Cat-CVD), hot-wire chemical vapor deposition (HWCVD), electron-cyclotron resonance (ECR) CVD, inductively coupled plasma (ICP) CVD, a combination of these or other suitable dielectric deposition technique(s). Structure 1001 results.

Referring now to FIG. 7 and step 1100, the method of fabricating device 100 further includes dispensing photo-resist layer 1110 over structure 1001 of FIG. 6, patterning resist layer 1110, and then implanting an ion species into first dielectric layer 220 and into semiconductor substrate 110 through openings 1120 created in resist layer 1110 to create isolation regions 112, which define active area 114. According to an embodiment, photo-resist layer 1110 may include one or more layers of photo-resist with a thickness that ranges from about 0.2 microns to about 10 microns, although electron beam resist or other suitable patterning materials of other thicknesses also may be used. Patterning resist layer 1110 may include applying a mask over photo-resist layer 1110, exposing unmasked portions of photo-resist layer 1110 to an appropriate dose of photon or electron beam irradiation, and then developing photo-resist layer 1110 with an appropriate developer.

According to an embodiment, isolation regions 112 may be formed by implanting an ion species at an energy sufficient to drive the species through dielectric layer 220 and into barrier layer 218, channel layer 216, and buffer layer 214, thus damaging the crystal lattice for these layers, disrupting channel 217 within the isolation regions 112, and creating high resistivity semiconductor regions 222 within semiconductor substrate 110. According to an embodiment, one of N, boron (B), helium (He), hydrogen (H), or a combination of these or one or a combination of other suitable ion species may be implanted through openings 1120 in photo-resist layer 1110 to create high resistivity semiconductor regions 222 below upper surface 219 of semiconductor substrate 110. The depth of high resistivity semiconductor regions 222 depends on the thicknesses of first dielectric layer 220, barrier layer 218, channel layer 216, and buffer layer 214 as well as the accelerating potential and mass of the ion species implanted into semiconductor substrate 110. Both the presence of the implanted species as well as the damage caused within the crystal lattice within semiconductor substrate 110 render the affected high resistivity regions 222 semi-insulating, thus forming isolation regions 112. Structure 1101 results. The remaining areas protected by resist layer 1110 that are not exposed to ion implantation, etching, or otherwise rendered high resistivity or removed are included in the active area 114. After formation of isolation region 112, resist layer 1110 is removed from structure 1101 using appropriate solvents (not shown).

In other embodiments (not shown), isolation regions 112 are formed by removing (e.g., etching) dielectric layer 220, barrier layer 218, channel layer 216, and buffer layer 214 within the isolation regions 112 to remove channel 217 within the isolation regions 112. In these embodiments using etched isolation, the etching of semiconductor layers that overlie semiconductor substrate 110 including barrier layer 218, channel layer 216, and buffer layer 214 may terminate within one of these layers. Alternatively, the etching may terminate on upper surface 213 of portion 110b of semiconductor substrate 110 or may extend into semiconductor substrate 110 below upper surface 213. In some embodiments, etching may be used in conjunction with ion implantation to create isolation regions 112.

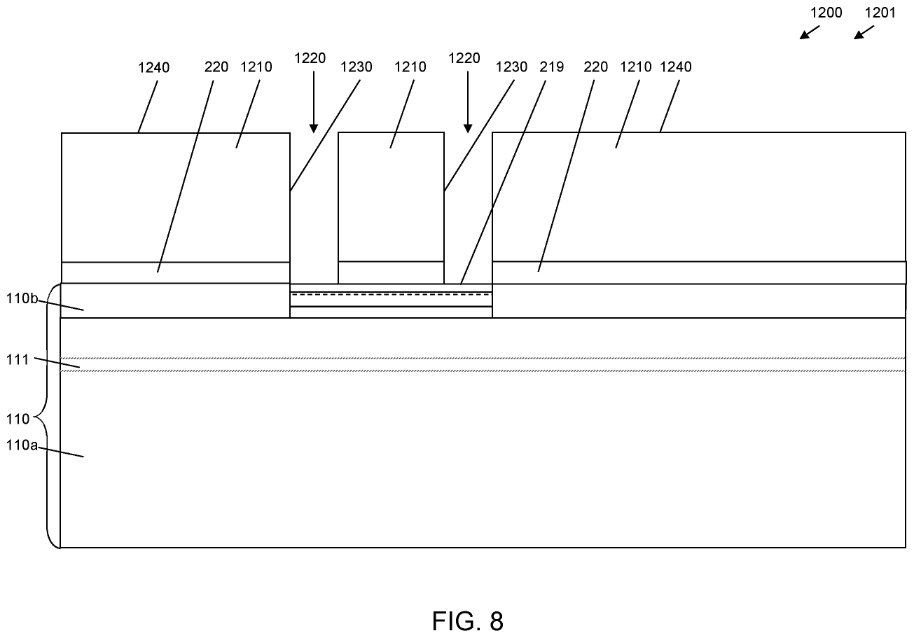

Referring now to FIGS. 8-10 and steps 1200-1400, the method of fabricating device 100 further includes forming drain electrode 122 and source electrode 124 of FIG. 2. FIG. 8 and step 1200 depicts and describes creating openings 1220 for forming source electrode 124 and drain electrode 122 of FIGS. 1-3 according to an embodiment. In an embodiment, openings 1220 in resist layer 1210 are created by dispensing resist layer 1210 over structure 1101 of FIG. 7, and patterning resist layer 1210. According to an embodiment, resist layer 1210 may include one or more layers of photo-resist with a thickness that ranges from about 0.5 microns to about 10 microns, although electron beam resist or other suitable patterning materials or of other thicknesses may be used. Patterning resist layer 1210 to create openings 1220 may include applying a mask over resist layer 1210, exposing unmasked portions of resist layer 1210 with an appropriate dose or doses of photon and/or electron beam irradiation and then developing the resist layer 1210 with an appropriate developer. In an embodiment, the openings 1220 may be aligned to isolation regions 112 using alignment marks or other appropriate means created using a separate alignment mark level (not shown) also aligned to isolation regions 112. In other embodiments, step 1200 may be a first step in the method, requiring no alignment to a prior process layer. In an embodiment, a “lift-off profile” is used to create a profile for the sidewalls 1230 within the openings 1220 such that the openings 1220 are slightly larger at the bottom of the openings 1220 near the upper surface 219 of semiconductor substrate 110 than at the resist upper surface 1240. The lift-off profile ensures that subsequent deposition of metal will not create metal connection bridges between metal deposited over the upper surface 1240 of resist layer 1210 and within openings 1220 over and in contact with semiconductor substrate 110. A plasma de-scum process may be used to remove residual traces of undeveloped resist material (not shown) from the exposed upper surface of the first dielectric layer 220 within openings 1220.

In an embodiment, an etch process is used to remove portions of dielectric layer 220 (within openings 1220) thus exposing top substrate surface 219 within openings 1220. In an embodiment, the first dielectric layer 220 is removed using an appropriate dry or wet etch technique or a combination of both. In an embodiment, dry etching of first dielectric layer 220 to expose a portion of the top substrate surface 219 may include reactive ion etching (RIE), inductively coupled plasma (ICP) etching, electron-cyclotron resonance (ECR) etching or a combination of these techniques, though other suitable techniques may be used. Suitable fluorine (F)-based dry etch chemistries such as sulphur hexafluoride (SF₆), carbon hexafluoride (C₂F₆), carbon tetrafluoride (CF₄), or other suitable dry etch chemistries may be used. The dry etch chemistries may be supplemented with argon (Ar) or oxygen (O₂) or a combination of these or other suitable gases to prevent polymer formation within the openings 1220 when etching the first dielectric layer 220. Wet etching of the first dielectric layer 220 may be accomplished using hydrofluoric acid (HF), dilute HF, buffered oxide etch (BOE), hot phosphoric acid (H₃PO₄), or other suitable wet chemistry technique. In an embodiment, when first dielectric layer 220 includes a SiN layer deposited over an Al₂O₃ layer, first dielectric layer 220 may be etched using an F-based dry etch such as RIE, ICP, or ECR to remove the SiN layer followed by a BOE wet etch to remove the Al₂O₃ layer, exposing portions of top substrate surface 219 underlying openings 1220. In other embodiments, when a CVD diamond layer or other insulating thermal conductor is deposited directly over and in contact with semiconductor substrate 110, or alternatively, over a lower thermal conductivity insulating layer such as one of Al₂O₃, SiN, or a combination of these or other suitable layer(s), an 02 plasma may be used to etch the CVD diamond layer. Suitable wet-etch or dry etch chemistries may be used to remove the underlying (e.g. Al₂O₃ or SiN) layer(s). Structure 1201 results.

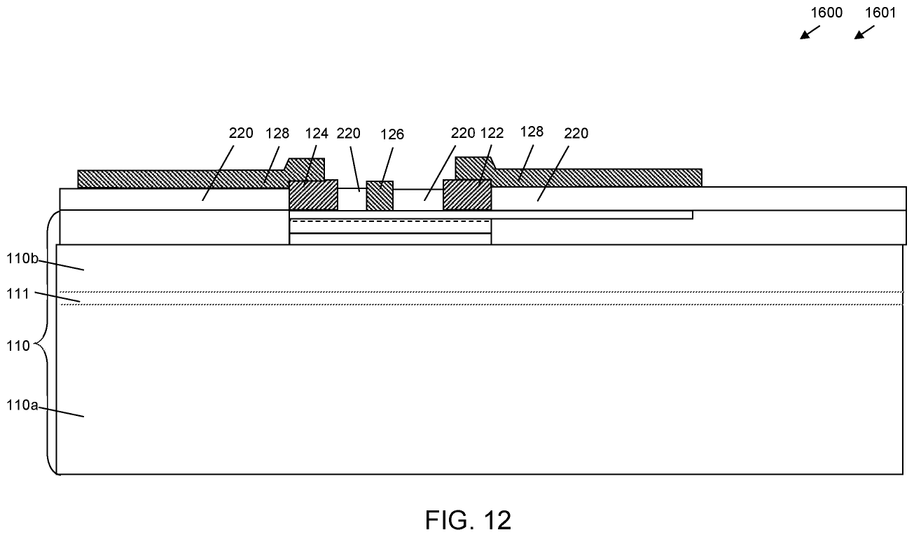

FIG. 12 depicts depositing an ohmic metal layer 1310 to form contacts 1320, in step 1300 according to an embodiment. In an embodiment, ohmic metal layer 1310 is deposited over and in contact with upper surface 1240 of resist layer 1210 and into the openings 1220 of structure 1201 of FIG. 8 in contact with the exposed portions of the upper surface 219 of the semiconductor substrate 110. In an embodiment, ohmic metal layer 1310 may include a multi-layer stack of metals, including metal layers, from bottom to top, of titanium (Ti), Al, molybdenum (Mo), and Au, although other suitable materials may be used. In an embodiment, the thickness of the Ti layer may range from about 50 to about 500 angstroms, the thicknesses of the Al layer may range from about 500 to about 5000 angstroms, the thicknesses of the Mo layer may range from about 500 to about 1000 angstroms, and the thickness of the Au layer may range from about 500 to about 1000 angstroms, although other ranges of thicknesses may be used for each layer. In some embodiments, one or more of the Ti, Al, Mo, or Au layers may be omitted or substituted for other suitable materials. In an embodiment, the multi-layer stack of metals may be deposited by evaporation, sputtering, PVD, ALD, or other suitable deposition techniques. In an embodiment, the excess regions of ohmic metal layer 1310 not within the openings 1220 may be removed using a “lift-off” technique by immersing the wafer in solvents that penetrate resist layer 1210 through sidewalls 1230 (and/or other sidewalls, not shown) in the resist layer 1210. This causes the ohmic metal layer 1310 that was in contact with the upper surface of resist layer 1310 but not directly in contact with semiconductor substrate 110 to wash away. Contacts 1320 (or the portions of ohmic metal layer 1310 that are directly in contact with semiconductor substrate 110) remain on the upper surface of the semiconductor substrate 110. In other embodiments, other techniques known in the art such as etching may be used to pattern contacts 1320. Structure 1301 results.

As depicted in FIG. 10 and step 1400, the method further includes annealing contacts 1320 of structure 1301 of FIG. 9 to form drain electrode 122 and source electrode 124, according to an embodiment. In an embodiment, annealing contacts 1320 includes loading structure 1301 of FIG. 9 (after removal of resist layer 1210) into a rapid thermal annealing (RTA) system or thermal furnace and raising the temperature of the semiconductor substrate 110 and contacts 1320 to an appropriate temperature in the presence of a suitable ambient gas or mixture. In an embodiment, an RTA system may be used to anneal contacts 1320 to form drain electrode 122 and source electrode 124 at a temperature between about 500 and about 900 degrees Celsius (° C.) for 15 to 120 seconds, though other suitable temperatures and times may be used. In an embodiment, the RTA system may use one of nitrogen (N₂), oxygen (O₂), or forming gas ambient, though a combination of these or other suitable ambient gasses may be used. In an embodiment, the time, temperature, and ambient gasses are optimized to create an ohmic contact between drain electrode 122 and channel 217, and between source electrode 124 and channel 217. The ohmic contact resistance between source electrode 124 or drain electrode 122 and channel 217 may between about 0.05 and about 1.00 ohm-mm though other contact resistance values may be used. Structure 1401 results.

Referring now to FIG. 11 and step 1500, the method of fabricating device 100 further includes forming gate electrode 126 according to an embodiment. In an embodiment, forming gate electrode 126 includes applying and patterning resist layer(s) to structure 1401 of FIG. 10, and etching first dielectric layer 220 analogous to steps described in FIG. 8 and step 1200. The embodiment further includes depositing gate metal and lifting-off gate metal analogous to the steps described in FIG. 9 and step 1300.

In an embodiment, photo resist or e-beam resist is patterned to create an opening in the resist in a manner analogous to the description given for FIG. 8 and step 1200. Using the opening created in the resist layer, first dielectric layer 220 may be etched to form a gate contact opening, thus exposing a portion of the top substrate surface 219, according to an embodiment. In an embodiment, one or more layers of gate metal may then be deposited over the opening in the resist to form gate electrode 126 over a top substrate surface 219. Depositing gate metal to form gate electrode 126 may include depositing a multi-layer stack that includes one or more metal layers and/or other suitable materials. A first layer within the multi-stack used to form gate electrode 126 may include titanium (Ti), nickel (Ni), platinum (Pt), copper (Cu), palladium (Pd), chromium (Cr), tungsten (W), iridium (Ir), nickel silicide (Ni_{X}Si_{Y}), poly-silicon or other suitable materials. The first layer may be between about 30 and about 2,000 angstroms in thickness, although other thickness values may be used. One or more layers that act as conductive layers may be deposited over the first layer to form gate electrode 126, according to an embodiment. The conductive layer(s) may include Au, Ag, Al, Cu, Ti or other substantially conductive materials. The conductive layer(s) may be between about 50 and about 20,000 angstroms in thickness, although other thickness values may be used. Optionally, one or more barrier metal layers may be placed between the first layer and the conductive layer(s), where the barrier metal layer(s) may include materials such as Ni, Pt, Cu, Pd, Cr, W, Ir, Ni_{X}Si_{Y} or other substantially refractive materials that act as a barrier between the portion of the first layer that contacts semiconductor substrate 110 and the conductive layer(s). The barrier metal layer(s) may be between about 50 and about 10,000 angstroms in thickness, although other thickness values may be used. In an embodiment, the various layers used to form gate electrode 126 may be deposited by evaporation, sputtering, PVD, ALD, or other suitable deposition technique(s).

In an embodiment, annealing may be used to stabilize gate electrode 126 analogous to annealing of the source electrode 124 and drain electrode 122 of structure 1401 of FIG. 10 and step 1400. Annealing gate electrode 126 includes placing the semiconductor substrate 110 with gate electrode 126 into a RTA or thermal furnace, raising the temperature of semiconductor substrate 110 and gate electrode 126 to an appropriate temperature in the presence of a suitable ambient gas or mixture. In an embodiment, an RTA system may be used to anneal gate electrode 126 at a temperature between about 200° C. and about 600° C. for 15 seconds to about 2 hours, although other suitable temperatures and times may be used. In an embodiment, the RTA system may use one of N₂, O₂, air, or forming gas ambient, though a combination of these or other suitable ambient(s) may be used. In an embodiment, the time, temperature, and ambient gasses are optimized to stabilize the gate electrode 126. Structure 1501 results.

It should be appreciated that other methods may be used to form gate electrode 126 without departing from the scope of the inventive subject matter. In methods for fabricating these other embodiments (not shown), gate electrode 126 may be formed by patterning a first resist layer to form an opening, etching first dielectric 220 to create an opening exposing top substrate surface 219, and then removing the first resist layer. In this embodiment, forming gate electrode 126 then includes patterning an opening in a second resist layer aligned over the opening created in first dielectric layer 220 to expose top substrate surface 219. The opening in the second resist layer may be smaller or larger than the opening in first dielectric layer 220. In other embodiments, gate metal may be disposed over a gate dielectric such as SiO₂, HfO₂, Al₂O₃, or similar materials. The gate dielectric may be deposited over and above top substrate surface 219, according to an embodiment. In still other embodiments, gate electrode 126 may be formed using gate metal that is deposited over semiconductor substrate 110 and is then defined by patterning photo resist, and then etching the gate metal. In whichever embodiment or method is selected to form gate electrode 126, gate metal may then be deposited using the methods described in connection with the formation of gate electrode 126 shown in FIG. 11.

Referring now to FIG. 12 and step 1600, the method of fabricating device 100 further includes depositing and patterning first interconnect metal 128 over drain electrode 122, source electrode 124, and first dielectric 220 of structure 1501 of FIG. 11 according to an embodiment. In an embodiment, patterning first interconnect metal 128 may be accomplished by applying and patterning resist layers (not shown) analogous to step 1000 of FIG. 6, depositing first interconnect metal 128, and removing the resist layers and overlying first interconnect metal 128 in a lift-off configuration, analogous to step 1200 in FIG. 8. In an embodiment, first interconnect metal 128 may be formed by metal layers and deposition techniques analogous to the descriptions of step 1300 in FIG. 9 for forming contacts 1320. In an embodiment, first interconnect metal 128 is formed by depositing one or more adhesion and conductive metal layers into openings (not shown) patterned into the resist layers applied to the partially-formed device as described above. In an embodiment, the adhesion layer(s) may be deposited first, followed by deposition of the conductive layer(s). In an embodiment, the adhesion and conductive layers may be deposited in the same deposition step. The adhesion layer(s) may include one of Ti, Ni, Cr or other suitable adhesion layer material(s). The adhesion layer(s) may be between about 50 and about 2,000 angstroms in thickness, although other thickness values may be used. The conductive layer(s) may include Cu, Au, Al, or Ag, although other suitable materials may be used. The conductive layer(s) may be between about 200 and about 40,000 angstroms in thickness, although other thickness values may be used. The adhesion and conductive layers used to form first interconnect metal 128 may be deposited over and in contact with drain electrode 122 and source electrode 124, or gate electrode 126, according to an embodiment. In an embodiment, first interconnect metal 128 may also be deposited to electrically contact inductor 130, transmission line 132, and/or other of first conductive features. In an embodiment, the adhesion layer(s) and conductive layer(s) may be formed by sputtering, evaporation, or electro-plating.

In an embodiment, after applying and patterning resist layers and depositing the first interconnect metal 128, the resist layers and metals deposited over the resist layers and not included with the portions of first interconnect metal 128 that contact electrodes 122, 124, 126, and substrate 110 are removed using solvents analogous to those described in conjunction step 1300 in FIG. 9. In other embodiments, first interconnect metal 128 may be formed by depositing adhesion and conductive layers that are then patterned by suitable dry or wet chemical etching techniques. Structure 1601 results.

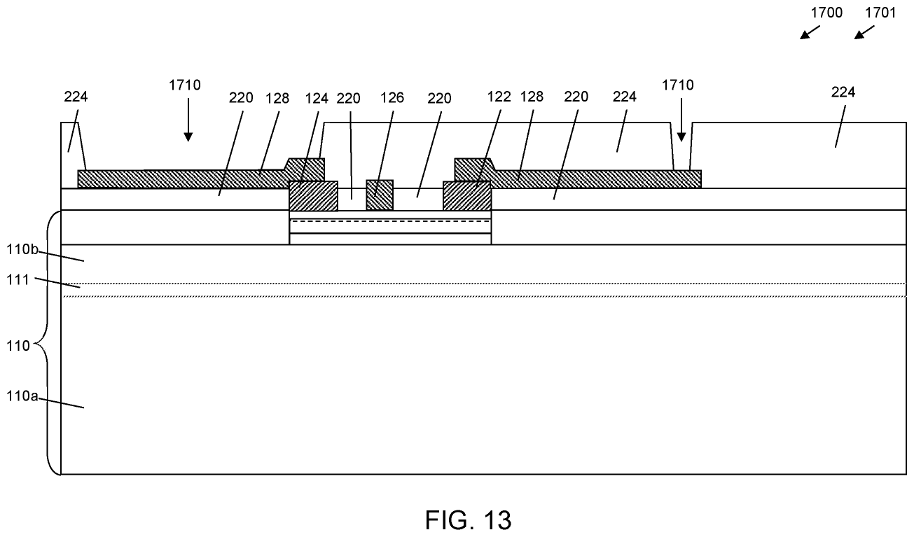

As depicted in FIG. 13 and step 1701 the method for fabricating device 100 includes depositing second dielectric layer 224 over semiconductor substrate 110, drain electrode 122, source electrode 124, gate electrode 126, first interconnect metal 128, and first dielectric layer 220 of structure 1601 of FIG. 12 according to an embodiment. In an embodiment, second dielectric layer 224 may include one of silicon nitride, SiO₂, HfO₂, diamond, poly-diamond, AlN, BN, SiC, or a combination of these or other insulating materials. The total thickness of the layers used to form second dielectric layer 224 may be between about 100 and about 10,000 angstroms in thickness, although other thickness values may be used. Second dielectric layer 224 may be deposited using low pressure chemical vapor deposition (LPCVD), plasma-enhanced chemical vapor deposition (PECVD), sputtering, physical vapor deposition (PVD), atomic layer deposition (ALD), catalytic chemical vapor deposition (Cat-CVD), hot-wire chemical vapor deposition (HWCVD), electron-cyclotron resonance (ECR) CVD, inductively coupled plasma (ICP) CVD, a combination of these or other suitable dielectric deposition technique(s). Without departing from the scope of the inventive subject matter, additional process steps (not shown) may be employed to deposit additional metal layers for additional connections between gate electrode 126, first interconnect metal 128 and other circuitry that may be electrically coupled to device 100.

In an embodiment, additional process steps analogous to FIG. 8, step 1200 may be used to create second dielectric openings 1710. In an embodiment, second dielectric layer 224 may be patterned by placing a resist layer (not shown) over second dielectric layer 224, and patterning the resist layer to form openings to portions of the second dielectric layer 224 over the first interconnect metal electrodes 128 that are in contact with drain electrode 122 and source electrode 124 (e.g., using a technique analogous to the patterning of the resist layer 1210 to form openings 1220 depicted in FIG. 8 and step 1200). Second dielectric layer 224 may then be etched through the openings using a technique analogous to the etching of first dielectric 124 as depicted in FIG. 8 and step 1200. Structure 1701 results.

As depicted in FIG. 14, step 1800 includes forming one or more first conductive feature(s) that may include inductor 130, transmission line 132, and top interconnect structure 134 over first interconnect metal 128, of structure 1701 of FIG. 13, according to an embodiment. More specifically, in an embodiment, at least some first conductive features may be formed to directly contact the portions of first interconnect metal 128 that are coupled to drain electrode 122, source electrode 124, and gate electrode 126. In other embodiments (not shown) one or more conductive features may be formed over a portion of the second dielectric layer 224 to provide a top electrode of a metal-insulator-metal (MIM) capacitor.

In an embodiment, first conductive features such as inductor 130, transmission line 132, and top interconnect structure 134 may be formed over first dielectric 220 and/or second dielectric layer 224 by depositing an adhesion layer of Ti, Ni, or Cr and then a second conductive layer of Cu, Au, Al, although other suitable materials may be used. The adhesion layer may be between about 100 and about 2,000 angstroms in thickness, although other thickness values may be used. The conductive layer may include Cu, Au, Al, or Ag, although other suitable materials may be used. The conductive layer may be between about 1000 and about 100,000 angstroms in thickness, although other thickness values may be used. First conductive features such as inductor 130, transmission line 132, and top interconnect structure 134 may be formed by sputtering, evaporation, electro-plating, or other suitable technique. In an embodiment, forming first conductive features 130, 132, and 134 may be accomplished by electro-plating, although other techniques such as lift-off may be used. In other embodiments, first conductive features 130, 132, and 134 may be deposited using a blanket film that is then patterned by suitable dry or wet chemical etching techniques known in the art. Structure 1801 results.

In some embodiments, additional process steps for depositing and patterning one or more additional dielectric layers for moisture and chemical protection may also be employed. The additional dielectric layer(s) may include one of silicon nitride (Si₃N₄), silicon dioxide (SiO₂), aluminum oxide (Al₂O₃), a combination of these or other suitable insulating dielectric layer(s). The additional dielectric layer(s) may have a total thickness of between about 100 and about 20,000 angstroms, although other thickness values may be used. The additional dielectric layer(s) may be formed using PECVD, ALD, ICP, ECR, Cat-CVD, HWCVD, sputtering, or other suitable deposition techniques.

Referring now to FIG. 15 and step 1900, the method of fabricating device 100, includes forming through wafer via 168 within semiconductor substrate 110. In an embodiment, structure 1801 of FIG. 14 is flipped over and mounted by adhesive layer 1910 to carrier substrate 1920. In an embodiment, semiconductor substrate 110 is then thinned to a final substrate thickness 1930 exposing bottom substrate surface 210 using conventional grinding, lapping, and/or polishing techniques. In an embodiment, final substrate thickness 1930 of semiconductor substrate 110 may be between about 10 and about 500 microns though other thicknesses may be used. A suitable masking material (not shown) is then applied to bottom substrate surface 210, according to an embodiment. The masking material may include Al, Ni, Cr, photo-resist, indium tin oxide (ITO) or other suitable materials. In an embodiment, one or more openings (not shown) are created in the masking material.

In an embodiment, the masking material is removed after etching an opening for through wafer via 168 in semiconductor substrate 110. In an embodiment, back-metal layer 1960 is deposited over bottom substrate surface 210 using a first adhesion layer that contacts lower surface 210 and through wafer via sidewalls 280 and recessed surface 282 of through wafer via 168, and a second conductive layer that overlies the first adhesion layer. In an embodiment, the adhesion layer may be selected from Ti, Ni, Cr, Ti—W, Au, Cu, Al, a combination of these, or other materials that adhere to semiconductor substrate 110. In an embodiment, the adhesion layer may be deposited over bottom substrate surface 210 using one or more of sputtering, evaporation, electro-plating or other suitable technique(s). In an embodiment, the conductive layer may be selected from one of Au, Pd, Cu, Al, tin (Sn), Au—Sn eutectic, a combination of these, or other materials that adhere to the adhesion layer and have sufficient electrical conductivity, thermal conductivity, and solder wetting properties. In an embodiment, the conductive layer may be deposited using one or more of sputtering, evaporation, electro-plating, electro-less plating, or other suitable technique(s). In some embodiments, a barrier layer may be inserted between the adhesion layer and the conductive layer to prevent solder applied to back metal layer 1960 to consume the adhesion layer. The barrier layer may include one of vanadium (V), Ti, Ni, or other suitable materials. The barrier layer may be deposited by sputtering, evaporation, plating, or other suitable technique(s).

In an embodiment, through wafer via 168 is created by etching semiconductor substrate 110 using a plasma etch technique. When etching is complete, through wafer via 168 extends from bottom substrate surface 210 and terminates on a first interconnect metal bottom surface 1940. As such, as shown in FIG. 15, through wafer via 168 penetrates through both lower portion 110a and portion 110b of semiconductor substrate 110 and through insulation layer 111. In other embodiments (not shown), through wafer via 168 may terminate on top interconnect structure bottom surface 1950. In an embodiment, plasma etching techniques may be used to create through wafer via 168 in semiconductor substrate 110. These techniques may include reactive ion etching (RIE), inductively coupled plasma (ICP) etching, electron-cyclotron resonance (ECR) etching, or a combination of these techniques, though other suitable techniques may be used. The chemistries selected for the plasma etching techniques depend largely on the materials that comprise semiconductor substrate 110 and the semiconductor layers that may overlie semiconductor substrate semiconductor substrate 110. For embodiments that include GaN in high resistivity semiconductor layer 222, Cl-based etch chemistries such as Cl, BCl₃, combinations of these, or other suitable chemistries may be used. For both F-based and Cl-based etching, O₂ or Ar, or other suitable gases may be added to prevent polymer formation during etching. Structure 1901 results.

Referring now to FIG. 16 and step 2000, the method of fabricating device 100, includes patterning back metal layer 1960 to form back metal 140 and backside contact 142 (second conductive features) over bottom substrate surface 210 of structure 1901 of FIG. 15. According to an embodiment, a backside masking layer 2010 is disposed over the surface 242 of back metal layer 1960. Backside masking material 2010 is patterned using appropriate photo lithography and/or etching techniques that are familiar to one with skill in the art. Openings 150 are then etched into back metal layer 1960 through openings in the masking layer 2010, thus forming back metal 140 and backside contact(s) 142. Substrate bottom surface 210 is exposed through the openings 150 in back metal layer 1960. Structure 2001 results.

Referring now to FIG. 17 and step 2100, the method of fabricating device 100, includes removing backside masking material 2010, patterning a cavity masking layer 2110, and etching a cavity opening 2120. In an embodiment, cavity masking layer 2110 is disposed over bottom back metal layer surface 242 and over substrate surface 210 inside first conductor-less region(s) 150 of structure 2001 of FIG. 16. In an embodiment, and analogous to forming through wafer via 168 as discussed in conjunction with FIG. 15 and step 1900, cavity masking layer 2110 may include Al, Ni, Cr, photo-resist, indium tin oxide (ITO) or other suitable materials. In an embodiment, plasma etching techniques may be used to create cavity opening 2120 in semiconductor substrate 110. When etching is complete, cavity opening 2120 extends from bottom substrate surface 210 and terminates on a bottom surface 113 of insulation layer 111. These techniques may include reactive ion etching (RIE), inductively coupled plasma (ICP) etching, electron-cyclotron resonance (ECR) etching, or a combination of these techniques, though other suitable techniques may be used. The chemistries selected for the plasma etching techniques depend largely on the materials that comprise semiconductor substrate 110 and insulation layer 111. In an embodiment, the materials used to etch semiconductor substrate 110 to form cavity opening 2120 include xenon difluoride (XeF₂)-based etch chemistries when enabled the use of bottom surface 113 of insulation layer 111 as an etch-stop structure to control the depth of cavity opening 2120. As such, in step 2100, a portion of insulation layer 111, which in embodiments includes SiO₂, serves as an etch stop for such etch chemistries. For both F-based and Cl-based etching, O₂ or Ar, or other suitable gases may be added to prevent polymer formation during etching. Structure 2101 results.

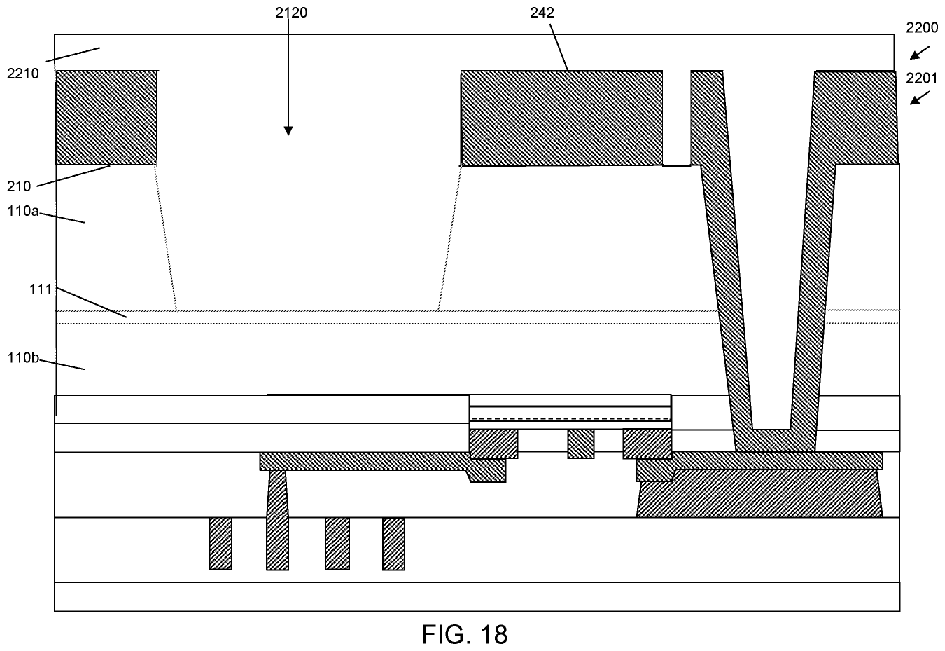

Referring now to FIG. 18 and step 2200, the method of fabricating device 100, includes removing cavity masking layer 2110 from structure 2101 of FIG. 17 and then disposing dielectric material 2210 over substrate bottom surface 210 within conductor-less regions 150 and surfaces 242 of the second conductive features 140, 142 and into cavity opening 2120. In an embodiment, dielectric material 2210 may include one or more of photo-imageable benzocyclobutene (BCB), non-photo-imageable BCB, polymide, epoxy, spin-on glass, or a combination of these or other suitable dielectric materials. In an embodiment, dielectric material 2210 may be deposited by spin-coating, spray coating, or other suitable technique. In an embodiment, dielectric material 2210 fills cavity opening 2120 and conductor-less region(s) 150. Structure 2201 results.

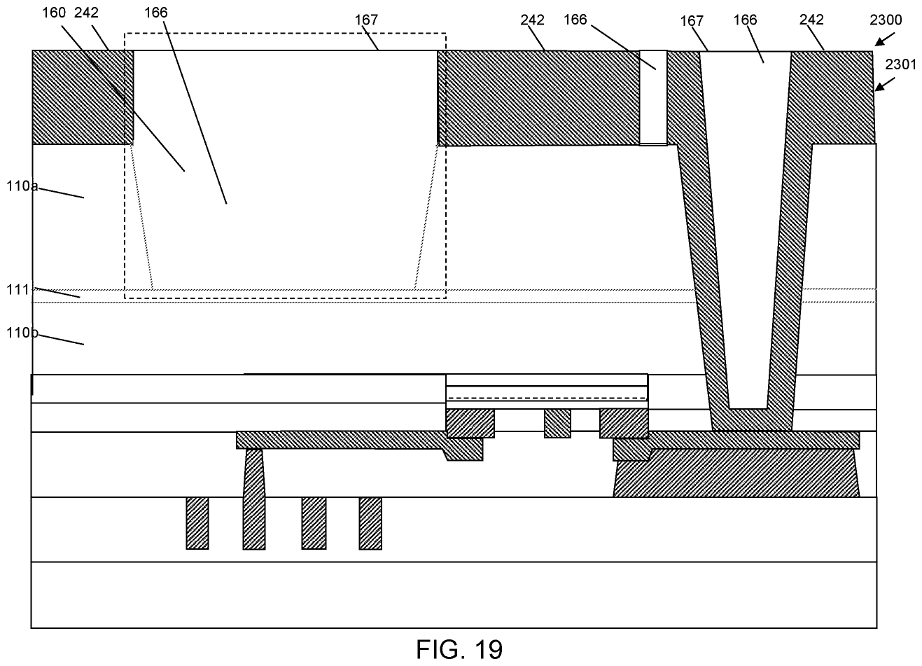

Referring now to FIG. 19 and step 2300, the method of fabricating device 100, includes removing excess dielectric material 2210 of structure 2201 of FIG. 18 to expose bottom back metal surface 242, and curing dielectric material 2210, to create dielectric medium 166 such that dielectric medium surface 167 is at or below the plane of bottom back metal surface 242. In an embodiment, photo-imageable BCB may be used. In this embodiment, excess dielectric material 2210 may be removed by flood exposing dielectric material 2210 with an appropriate light source such as a contact aligner or stepper and then using an appropriate developer to remove a portion of the dielectric material 2210 to a depth at the plane of bottom back metal surface 242. In an embodiment, after bottom back metal surface 242 has been exposed, dielectric material 2210 may be cured using a hard bake or other appropriate methods. In other embodiments where non photo imageable materials are used to create dielectric material 2210, excess dielectric material 2210 may be removed by dry etching dielectric material 2210 until bottom back metal surface 242 is exposed. Structure 2301 results.

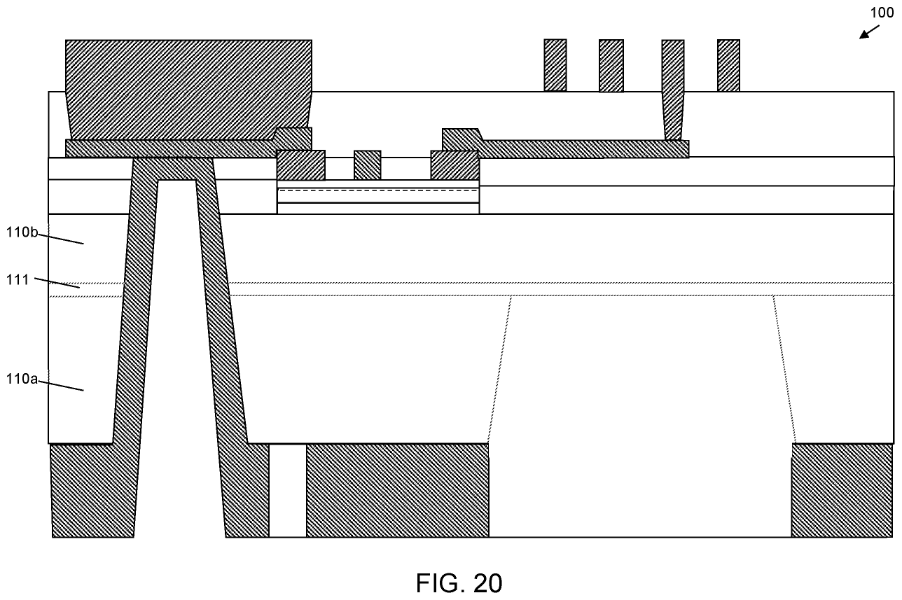

Referring now to FIG. 20, the method of fabricating device 100 includes immersing structure 2301 from FIG. 19 in suitable solvents that dissolve adhesive layer 1910, thus separating semiconductor substrate 110 from carrier wafer 1920 of FIG. 15 (not shown). The semiconductor wafer including device 100 may then be further processed to singulate device 100 from the wafer. The finished device 100 results.

It is to be appreciated that a device and method of forming the device has been disclosed. In some aspects, the techniques described herein relate to a method, including: providing a semiconductor substrate including a first region of silicon, a second region of silicon, a layer of silicon dioxide disposed between the first region and the second region of the substrate, and a layer of gallium nitride on a first surface of the substrate; forming a transistor over the first surface of the substrate, wherein forming the transistor includes forming a control electrode, a first current-conducting electrode, and a second current-conducting electrode over the first substrate surface; forming a first conductive feature over the first surface of the substrate and electrically coupling the first conductive feature to one of the control electrode, the first current-conducting electrode, or the second current-conducting electrode; forming a second conductive feature over a second surface of the substrate, wherein the second conductive region covers only a portion of the second substrate surface to define a first conductor-less region; and forming a first cavity within the first conductor-less region that includes a first upper cavity surface defined by a surface of the layer of silicon dioxide, wherein the first upper cavity surface is directly below the first conductive feature.

In some aspects, the techniques described herein relate to a method, including: providing a silicon-on-insulator (SOI) substrate including a layer of gallium nitride on a first surface of the SOI substrate; forming a device over the first surface of the substrate; forming a first conductive feature over the first surface of the substrate and electrically coupling the first conductive feature to the device; and forming a first cavity in a second surface of the SOI substrate directly below the first conductive feature, wherein the first cavity includes first upper cavity surface defined by a surface of a layer of silicon dioxide in the SOI substrate.

In some aspects, the techniques described herein relate to a device, including: a semiconductor substrate including a first region of silicon, a second region of silicon, a layer of silicon dioxide disposed between the first region and the second region of the substrate, and a layer of gallium nitride on a first surface of the substrate; a transistor formed over the first surface of the substrate, the transistor including a control electrode, a first current-conducting electrode, and a second current-conducting electrode over the first substrate surface; a first conductive feature formed over the first surface of the substrate, wherein the first conductive feature is electrically coupled to one of the control electrode, the first current-conducting electrode, or the second current-conducting electrode; a second conductive feature formed over a second surface of the substrate, wherein the second conductive region covers only a portion of the second substrate surface to define a first conductor-less region; and a first cavity formed within the first conductor-less region that includes a first upper cavity surface defined by a surface of the layer of silicon dioxide, wherein the first upper cavity surface is directly below the first conductive feature.

For the sake of brevity, conventional semiconductor fabrication techniques may not be described in detail herein. In addition, certain terminology may also be used herein for the purpose of reference only, and thus are not intended to be limiting, and the terms “first”, “second” and other such numerical terms referring to structures do not imply a sequence or order unless clearly indicated by the context.

As used herein, a “node” means any internal or external reference point, connection point, junction, signal line, conductive element, or the like, at which a given signal, logic level, voltage, data pattern, current, or quantity is present. Furthermore, two or more nodes may be realized by one physical element (and two or more signals can be multiplexed, modulated, or otherwise distinguished even though received or output at a common node).

The foregoing description refers to elements or nodes or features being “connected” or “coupled” together. As used herein, unless expressly stated otherwise, “connected” means that one element is directly joined to (or directly communicates with) another element, and not necessarily mechanically. Likewise, unless expressly stated otherwise, “coupled” means that one element is directly or indirectly joined to (or directly or indirectly communicates with) another element, and not necessarily mechanically. Thus, although the schematic shown in the figures depict one exemplary arrangement of elements, additional intervening elements, devices, features, or components may be present in an embodiment of the depicted subject matter.

While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

What is claimed is:

1. A method, comprising:
providing a semiconductor substrate including a first region of silicon, a second region of silicon, a layer of silicon dioxide disposed between the first region and the second region of the substrate, and a layer of gallium nitride on a first surface of the substrate;
forming a transistor over the first surface of the substrate, wherein forming the transistor comprises forming a control electrode, a first current-conducting electrode, and a second current-conducting electrode over the first substrate surface;
forming a first conductive feature over the first surface of the substrate and electrically coupling the first conductive feature to one of the control electrode, the first current-conducting electrode, or the second current-conducting electrode;
forming a second conductive feature over a second surface of the substrate, wherein the second conductive region covers only a portion of the second substrate surface to define a first conductor-less region; and
forming a first cavity within the first conductor-less region that includes a first upper cavity surface defined by a surface of the layer of silicon dioxide, wherein the first upper cavity surface is directly below the first conductive feature.

2. The method of claim 1, wherein forming the first conductive feature includes forming at least a portion of at least one of an inductor and a capacitor over the first surface of the substrate.

3. The method of claim 1, wherein the first conductive feature is a component of a bulk acoustic wave (BAW) filter.

4. The method of claim 1, further comprising forming a dielectric medium within the first cavity, wherein the dielectric medium has a dielectric constant less than a dielectric constant of the semiconductor substrate.

5. The method of claim 4, wherein forming the dielectric medium within the first cavity includes disposing a dielectric medium selected from benzocyclobutene (BCB), polymide, epoxy, and spin-on glass into the first cavity.

6. The method of claim 1, further comprising:
forming an active region that includes the control electrode, the first current-conducting electrode, and the second current-conducting electrode; and
forming an isolation region that includes the first conductive feature.

7. The method of claim 6, wherein the second conductive region covers only the portion of the second substrate surface to define a second conductor-less region and further comprising:
forming a second cavity within the first conductor-less region that includes a second upper cavity surface defined by a surface of the active region, wherein the second upper cavity surface is directly below the transistor; and
forming a conductive material within the second cavity.

8. The method of claim 1, further comprising forming the first cavity by etching the semiconductor substrate using a dry etch technique.

9. The method of claim 1, further comprising forming the first cavity using a xenon difluorine (XeF₂) etching process.

10. A method, comprising:
providing a silicon-on-insulator (SOI) substrate including a layer of gallium nitride on a first surface of the SOI substrate;
forming a device over the first surface of the substrate;
forming a first conductive feature over the first surface of the substrate and electrically coupling the first conductive feature to the device; and
forming a first cavity in a second surface of the SOI substrate directly below the first conductive feature, wherein the first cavity includes first upper cavity surface defined by a surface of a layer of silicon dioxide in the SOI substrate.

11. The method of claim 10, wherein forming the first conductive feature includes forming at least a portion of at least one of an inductor and a capacitor over the first surface of the SOI substrate.

12. The method of claim 10, further comprising forming a dielectric medium within the first cavity, wherein the dielectric medium has a dielectric constant less than a dielectric constant of the SOI substrate.

13. The method of claim 10, further comprising the steps of:
forming an active region that includes the device; and
forming an isolation region that includes the first conductive feature.

14. The method of claim 13, further comprising forming a second cavity in the second surface of the SOI substrate, wherein the second cavity includes a second upper cavity surface defined by a surface of the active region, wherein the second upper cavity surface is directly below the device.

15. The method of claim 10, further comprising forming the first cavity using a xenon difluorine (XeF₂) etching process.

16. A device, comprising:
a semiconductor substrate including a first region of silicon, a second region of silicon, a layer of silicon dioxide disposed between the first region and the second region of the substrate, and a layer of gallium nitride on a first surface of the substrate;
a transistor formed over the first surface of the substrate, the transistor including a control electrode, a first current-conducting electrode, and a second current-conducting electrode over the first substrate surface;
a first conductive feature formed over the first surface of the substrate, wherein the first conductive feature is electrically coupled to one of the control electrode, the first current-conducting electrode, or the second current-conducting electrode;
a second conductive feature formed over a second surface of the substrate, wherein the second conductive region covers only a portion of the second substrate surface to define a first conductor-less region; and
a first cavity formed within the first conductor-less region that includes a first upper cavity surface defined by a surface of the layer of silicon dioxide, wherein the first upper cavity surface is directly below the first conductive feature.

17. The device of claim 16, wherein the first conductive feature includes at least a portion of at least one of an inductor and a capacitor over the first surface of the substrate.

18. The device of claim 17, wherein the first conductive feature is a component of a bulk acoustic wave (BAW) filter.

19. The device of claim 16, further comprising a dielectric medium disposed within the first cavity, wherein the dielectric medium has a dielectric constant less than a dielectric constant of the semiconductor substrate.

20. The device of claim 19, wherein the dielectric medium within the first cavity includes a dielectric medium selected from benzocyclobutene (BCB), polymide, epoxy, and spin-on glass.
